(19) United States
(12) Patent Application Publication
(10) Pub. No.: US 2010/0224909 A1
(43) Pub. Date: Sep. 9, 2010

(54) SEMICONDUCTOR DEVICE AND METHOD FOR FABRICATING THE SAME

(75) Inventors: Kanji OOHARA, Kyoto (JP); Takashi Miura, Ishikawa (JP)

Correspondence Address: MCDERMOTT WILL & EMERY LLP, 600 13TH STREET, NW, WASHINGTON, DC, 20005-3096, US

(73) Assignee: PANASONIC CORPORATION, Osaka (JP)

(21) Appl. No.: 12/783,135

(22) Filed: May 19, 2010

Related U.S. Application Data
(63) Continuation of application No. PCT/JP2009/002891, filed on Jun. 24, 2009.

(30) Foreign Application Priority Data
Aug. 29, 2008 (JP) 2008-221252

(51) Int. Cl. H01L 29/739; H01L 29/78; H01L 21/331

(52) U.S. Cl. 257/140; 257/330; 438/138; 438/268; 257/E21.384; 257/E29.262; 257/E29.198

(57) ABSTRACT

A first well region of a second conductivity type is formed in the portion of the semiconductor layer of the first conductivity type located in an element portion in which a vertical element is disposed, while a second well region of the second conductivity type is formed in the portion of the semiconductor layer located in a peripheral portion surrounding the element portion. A field insulating film is formed on the portion of the semiconductor layer located in a field portion interposed between the element portion and the peripheral portion. A depletion stop region of the first conductivity type having an impurity concentration higher than that of the semiconductor layer is formed in a surface portion of the semiconductor layer located under at least the portion of the field insulating film adjacent to the peripheral portion.

### CROSS-REFERENCE TO RELATED APPLICATION

This is a continuation of PCT International Application PCT/JP2009/002891 filed on Jun. 24, 2009, which claims priority to Japanese Patent Application No. 2008-221252 filed on Aug. 29, 2008. The disclosures of these applications including the specifications, the drawings, and the claims are hereby incorporated by reference in its entirety.

### BACKGROUND

The present disclosure relates to an insulated gate semiconductor device such as a vertical metal insulator semiconductor field effect transistor (MISFET) or a vertical insulated gate bipolar transistor (IGBT) in which a gate electrode is provided in a trench, and a method for fabricating the same.

In a vertical trench MISFET for power supply as a representative example of an insulated gate semiconductor device, it is typical that a large number of unit cells each having a transistor function and connected in parallel are provided in an element portion in a chip, and a channel stopper region connected to an equi-potential ring (EQR) electrode is provided in a chip peripheral portion (hereinafter referred to as the “peripheral portion”) surrounding the element portion. In the vertical trench MISFET, a channel is formed in the depth direction of a semiconductor main body to allow higher integration of the unit cells than in a gate planar MISFET in which a channel is formed in the plane direction of a semiconductor main body. Additionally, in the vertical trench MISFET, the width of the channel per unit area can be set large, which is extremely effective in reducing the ON resistance of an element.

A structure of a conventional N-channel trench MISFET will be described below with reference to FIGS. 20A-20C. FIG. 20A is an overall cross-sectional view of the conventional N-channel trench MISFET. FIG. 20B is a plan view of a peripheral portion R_{C} of the conventional N-channel trench MISFET. FIG. 20C is a cross-sectional view of the peripheral portion R_{C} of the conventional N-channel trench MISFET. Note that FIG. 20C is a cross-sectional view along the line A-A′ in FIG. 20B, and FIG. 20A is a cross-sectional view of the entire device including a cross-sectional structure along the line B-B′ in FIG. 20B. In FIG. 20B, the depiction of part of components is omitted.

As shown in FIG. 20A, the conventional N-channel trench MISFET is two-dimensionally divided into an element portion R_{A} having a vertical element, the peripheral portion R_{C} surrounding the element portion R_{A}, and a field portion R_{B} located between the element portion R_{A} and the peripheral portion R_{C}.

As shown in FIGS. 20A and 20C, the conventional N-channel trench MISFET is formed on a semiconductor main body 61 including a high-concentration N-type semiconductor substrate 62, and a low-concentration N-type epitaxial layer 63 formed on the top surface of the semiconductor substrate 62.

Also as shown in FIG. 20A, a P-type first base region 64 is selectively formed in the surface portion of the epitaxial layer 63 located in the element portion R_{A}, while a high-concentration N-type source region 65 is selectively formed in the surface portion of the first base region 64. In the element portion R_{A}, the remaining portion of the epitaxial layer 63 where the first base region 64 and the source region 65 are not formed serves as a low-concentration N-type drain region 66. In the element portion R_{A}, a trench 67a is formed to extend from the surface of the source region 65 through the source region 65 to reach the first base region 64.

Also as shown in FIG. 20A, a field oxide film 83 is formed on the portion of the epitaxial layer 63 located in the field portion R_{B}. Note that, in the field portion R_{B} also, the drain region 66 is provided in common to the element portion R_{A}.

As shown in FIGS. 20A-20C, a P-type second base region 94 is selectively formed in the surface portion of the epitaxial layer 63 located in the peripheral portion R_{C}. The second base region 94 is formed simultaneously with the first base region 64. In the surface portion of the second base region 94, a high-concentration N-type channel stopper region 95 is selectively formed. The channel stopper region 95 is formed simultaneously with the source region 65. Note that, in the peripheral portion R_{C} also, the drain region 66 is formed in common to the element portion R_{A} and the field portion R_{B}. Additionally, as shown in FIGS. 20A and 20B, a plurality of trenches 67c are formed in a mesh-like configuration in the peripheral portion R_{C} so as to extend from the surface of the channel stopper region 95 through the channel stopper region 95 to reach the second base region 94. The trenches 67c are formed simultaneously with the trench 67a.

In the element portion R_{A}, as shown in FIG. 20A, a polysilicon gate electrode 69 is formed on the portion of the first base region 64 located between the source region 65 and the drain region 66 with a gate oxide film 68 interposed between the first base region 64 and the polysilicon gate electrode 69. In the field portion R_{B}, a polysilicon gate wiring layer 84 electrically connected to the polysilicon gate electrode 69 is formed on the drain region 66 with the field oxide film 83 interposed therebetween. Note that a trench 67b is formed so as to extend through the polysilicon gate wiring layer 84.

Also as shown in FIGS. 20A and 20C, in the peripheral portion R_{C}, the field oxide film 83 provided in the field portion R_{B} has extended therefrom to span over the junction portion between the second base region 94 and the channel stopper region 95. In addition, an interlayer insulating film 70 is formed so as to cover the surface of the gate electrode 69 and the surface of the source region 65 except for the portion thereof adjacent to the trench 67a in the element portion R_{A}, cover the surface of the polysilicon gate wiring layer 84 in the field portion R_{B}, and cover the surface of the field oxide film 83 and the surface of the channel stopper region 95 except for the portions thereof adjacent to the trenches 67c (trench peripheries 97) in the peripheral portion R_{C}.

Also as shown in FIG. 20A, in the element portion R_{A}, a source electrode 71 made of aluminum is formed on the surface of the interlayer insulating film 70, on the surface portion of the source region 65 adjacent to the trench 67a, and in the trench 67a. In the field portion R_{B}, a gate metal wiring layer 85 is formed on the surface of the interlayer insulating film 70 and in the trench 67b. The gate metal wiring layer 85 is formed simultaneously with the source electrode 71. In the peripheral portion R_{C}, an EQR electrode 96 is formed on the surface of the interlayer insulating film 70 except for a scribe region R_{D}, on the surfaces of the trench peripheries 97 of the channel stopper region 95, and in the trenches 67c. Further, on the back surface of the semiconductor substrate 62, formed is a drain electrode 72.

In the conventional structure described above, when the MISFET is cut into a chip by dicing a wafer formed with the MISFET at the scribe region R_{D}, a cut surface Sc on the back-surface side of the semiconductor main body and that on the top-surface side of the semiconductor main body are each at the same potential due to a processing strain. Here, at the cut surface Sc on the top-surface side of the semiconductor main body, exposed is the channel stopper region 95. In the channel stopper region 95, the trenches 67c are formed in the mesh-like configuration to achieve sufficient electric contact with the EQR electrode 96 at the inner surfaces of the trenches 67c and at the surfaces of the trench peripheries 97 of the channel stopper region 95. As a result, the potential of the EQR electrode 96 is inevitably the same as the potential of the drain electrode 72 at the back surface of the semiconductor main body so that the EQR electrode 96 functions as a channel stopper. Therefore, it is possible to implement a highly reliable trench MISFET, i.e., insulated gate semiconductor device.

### SUMMARY

However, there is a problem that, in the conventional structure described above, a leakage current flows between the element portion and the peripheral portion to suppress a normal transistor operation.

It is therefore an object of the present disclosure is to prevent a leakage current from flowing between an element portion and a peripheral portion in a vertical insulated gate semiconductor device, and improve the reliability thereof.

To attain the object, the present inventors have examined the cause of the leakage current flowing between the element portion and the peripheral portion in the conventional structure described above, and made the following findings.

In a temperature cycle test in a high temperature/high humidity environment or the like which is performed on an insulated gate semiconductor device or the like, moisture (H₂O) may enter the inside of a chip from outside the device through the edge of the chip. The moisture that has entered the chip passes through the inside of the interlayer insulating film, and is rapidly diffused in the semiconductor main body (epitaxial layer) in the element portion. The moisture that has entered the chip is also downwardly diffused in the field insulating film to generate fixed charges in the field insulating film. As a result, the top surface portion of the epitaxial layer under the field insulating film is depleted. Through a depletion layer formed thereby, a leakage current flows between the impurity region formed in the epitaxial layer of the element portion and the impurity region formed in the epitaxial layer of the peripheral portion to suppress a normal transistor operation. Note that, in the following description, the leakge current flowing between the element portion and the peripheral portion indicates a leakage current flowing between the impurity region formed in the epitaxial layer of the element portion and the impurity region formed in the epitaxial layer of the peripheral portion.

In an insulated gate semiconductor device, when the interface between an oxide film and another insulating film, e.g., a nitride film is present above the epitaxial layer in the peripheral portion and when any interface charge occurs due to a fabrication-derived cause, a charge-up of the interface charge occurs in a temperature cycle test or the like in a high temperature/high humidity environment or the like to consequently cause concern about the occurrence of fixed charges in the field insulating film upon application of a predetermined voltage to the device. At this time, the top surface portion of the epitaxial layer located between the peripheral portion and the element portion is depleted, and a leakage current flows between the element portion and the peripheral portion to suppress a normal transistor operation.

In order to further increase the breakdown voltage of an insulated gate semiconductor device in future, it is an essential condition to reduce the impurity concentration of the epitaxial layer. However, when the impurity concentration of the epitaxial layer is reduced, concern about the occurrence of a leakage current due to the depletion of the top surface portion of an epitaxial layer as described above grows increasingly to increase the possibility of reduced reliability.

Thus, the cause of the reduced reliability of the conventional structure described above is that the ions that have entered the device from the outside thereof in the temperature cycle test or the like are fixed in the insulating film in the field portion located between the element portion and the peripheral portion, which causes the depletion of the entire top surface portion of the semiconductor main body in the field portion and a leakage current flowing between the element portion and the peripheral portion. The leakage current occurs with a drain voltage lower than a drain voltage corresponding to a breakdown voltage, and is monitored as a drain current larger than a normal drain current by about two orders of magnitude. It can be considered that this phenomenon occurs more prominently when the depletion of the top surface portion of the semiconductor main body is more likely to occur as a result of reducing the impurity concentration of the epitaxial layer in response to a request for retaining a high breakdown voltage characteristic placed on the insulated gate semiconductor device.

To prevent the occurrence of a leakage current due to movable ions, fixed charges, or the like which are present around an element region after a temperature cycle test in an insulated gate semiconductor device such as a vertical MISFET or a vertical IGBT in which a gate electrode is provided in a trench, the present inventors have made various studies on the relationship between the leakage current and each of an impurity distribution, a structure, an amount of fixed charges, and an electrostatic potential distribution using process/device simulation or the like, and consequently obtained the following idea.

That is, to provide a structure for suppressing the occurrence of a leakage current between the element portion and the peripheral portion in the insulated gate semiconductor device after the temperature cycle test and achieving an increase in the breakdown voltage of the device, a depletion stop region is additionally provided in the conventional structure including the element portion, the field portion, and the peripheral portion. The depletion stop region is disposed in the surface portion of the semiconductor layer in the field portion, and has the same conductivity type as that of the semiconductor layer and an impurity concentration higher than that of the semiconductor layer.

In the structure, even when ions that have entered the device from the outside thereof are fixed in the insulating film in the field portion in a temperature cycle test, and the top surface portion of the semiconductor layer in the field portion is locally depleted, the formation of a depletion layer over the entire surface of the semiconductor layer from the element portion to the peripheral portion is suppressed by the depletion stop region according to the present disclosure. Therefore, it is possible to suppress a leakage current from flowing between the element portion and the peripheral portion in the insulated gate semiconductor device after the temperature cycle test. In addition, even when the impurity concentration of the semiconductor layer is reduced in response to a future request for a higher breakdown voltage placed on an insulated gate semiconductor device, the depletion stop region according to the present disclosure can achieve an increased breakdown voltage without causing concern about the depletion of the top surface portion of the semiconductor layer in the field portion.

Note that the depletion stop region according to the present disclosure may also be formed to, e.g., protrude from within a well region in the peripheral portion into the semiconductor layer in the field portion as long as it is formed in the top surface portion of the semiconductor layer in the field portion. Here, the length of the protruding portion of the depletion stop region is not particularly limited.

Also, the depletion stop region according to the present disclosure may also be formed as a plurality of island portions spaced apart from each other in the top surface portion of the semiconductor layer in the field portion. In this case also, the effects of the present disclosure described above are obtainable. Here, the layout width of each of the island portions and the layout distance between the individual island portions may be the same.

Specifically, a semiconductor device according to the present disclosure is a semiconductor device divided in an element portion in which a vertical element is disposed, a peripheral portion surrounding the element portion, and a field portion interposed between the element portion and the peripheral portion, the semiconductor device including: a semiconductor substrate of a first conductivity type; a semiconductor layer of the first conductivity type formed on a top surface of the semiconductor substrate, and having an impurity concentration lower than that of the semiconductor substrate; a first well region of a second conductivity type formed in a portion of the semiconductor layer located in the element portion; a second well region of the second conductivity type formed in a portion of the semiconductor layer located in the peripheral portion; and a field insulating film formed on a portion of the semiconductor layer located in the field portion, wherein a depletion stop region of the first conductivity type having an impurity concentration higher than that of the semiconductor layer is formed in a surface portion of the semiconductor layer located under at least a portion of the field insulating film adjacent to the peripheral portion.

In the semiconductor device according to the present disclosure, in the surface portion of the semiconductor layer located under the portion of the field insulating film interposed between the element portion and the peripheral portion, formed is the depletion stop region having the same conductivity type as that of the semiconductor layer and the impurity concentration higher than that of the semiconductor layer. Accordingly, even when ions that have entered the device from the outside thereof in a temperature cycle test are fixed in the field insulating film, and the top surface portion of the semiconductor layer in the field portion is locally depleted thereby, the formation of a depletion layer over the entire surface of the semiconductor layer from the element portion to the peripheral portion is suppressed. Therefore, it is possible to suppress a leakage current from flowing between the element portion and the peripheral portion in the insulated gate semiconductor device after the temperature cycle test. In addition, even when the impurity concentration of the semiconductor layer is reduced in response to a future request for a higher breakdown voltage placed on a vertical insulated gate semiconductor device, the depletion stop region allows an increase in breakdown voltage without causing concern about the depletion of the top surface portion of the semiconductor layer in the field portion.

In the semiconductor device according to the present disclosure, the depletion stop region may be formed so as to extend in the second well region. In this case, a channel stopper region of the first conductivity type having an impurity concentration higher than that of the depletion stop region may be formed in a surface portion of the depletion stop region located in the second well region, and a first electrode electrically connected to the channel stopper region may be formed on the channel stopper region. Alternatively, a first electrode electrically connected to the depletion stop region may be formed on a portion of the depletion stop region located in the second well region. Note that the first electrode may be an EQR electrode.

In the semiconductor device according to the present disclosure, the depletion stop region may include a plurality of portions separated from each other.

In the semiconductor device according to the present disclosure, the first well region may be formed to adjoin the field insulating film, and a second electrode may be formed on a portion of the first well region adjacent to the field insulating film with an insulating film interposed therebetween. Here, the second electrode may also be formed on a portion of the field insulating film adjacent to the first well region.

The semiconductor device according to the present disclosure may further include: a trench formed so as to extend through the first well region; and a buried gate electrode formed in the trench with a gate insulating film interposed between the buried gate electrode and the wall surface of the trench. Here, the semiconductor device according to the present disclosure may further include: a source region of the first conductivity type formed in a surface portion of the first well region to adjoin the buried gate electrode, and further include: a body contact region of the second conductivity type formed in a surface portion of the first well region to adjoin each of the buried gate electrode and the source region. Additionally, the semiconductor device according to the present disclosure may further include: a source electrode formed over the source region and the body contact region so as to electrically connect the source region and the body contact region; and a drain electrode formed on the back surface of the semiconductor substrate.

In the semiconductor device according to the present disclosure, the vertical element may be a vertical MISFET, a vertical IGBT, or the like.

A method for fabricating a semiconductor device according to the present disclosure is a method for fabricating a semiconductor device divided in an element portion in which a vertical element is disposed, a peripheral portion surrounding the element portion, and a field portion interposed between the element portion and the peripheral portion, the method including the steps of: forming, on the top surface of a semiconductor substrate of a first conductivity type, a semiconductor layer of the first conductivity type having an impurity concentration lower than that of the semiconductor substrate; forming a depletion stop region of the first conductivity type having an impurity concentration higher than that of the semiconductor layer in a surface portion of the semiconductor layer located in at least a portion of the field portion adjacent to the peripheral portion; forming a field insulating film on a portion of the semiconductor layer located in the field portion so as to overlap at least a part of the depletion stop region; and forming a first well region of a second conductivity type in a portion of the semiconductor layer located in the element portion, while forming a second well region of the second conductivity type in a portion of the semiconductor layer located in the peripheral portion.

That is, the method for fabricating the semiconductor device according to the present disclosure allows the semiconductor device according to the present disclosure to be reliably fabricated. Therefore, it is possible to obtain the same effects as achieved by the foregoing semiconductor device according to the present disclosure.

Thus, according to the present disclosure, it is possible to implement an insulated gate semiconductor device such as a vertical MISFET or IGBT in which a leakage current resulting from movable ions, fixed charges, or the like around the element region after a temperature cycle test is suppressed from occurring, and to which a high breakdown voltage is ensured.

That is, the present disclosure relates to an insulated gate semiconductor device such as a vertical MISFET or IGBT and a method for fabricating the same. The present disclosure can achieve a higher breakdown voltage while preventing a leakage current from occurring due to movable ions, fixed charges, or the like present around the element region after a temperature cycle test, and is therefore extremely useful.

### BRIEF DESCRIPTION OF THE DRAWINGS

FIGS. 1A and 1B are a top-side plan view and a back-side plan view of a semiconductor device according to each of first to third example embodiments of the present disclosure.

FIG. 2 is a cross-sectional view showing a step of a method for fabricating the semiconductor device according to the first example embodiment.

FIG. 3 is a cross-sectional view showing a step of the method for fabricating the semiconductor device according to the first example embodiment.

FIG. 4 is a cross-sectional view showing a step of the method for fabricating the semiconductor device according to the first example embodiment.

FIG. 5 is a cross-sectional view showing a step of the method for fabricating the semiconductor device according to the first example embodiment.

FIG. 6 is a cross-sectional view showing a step of the method for fabricating the semiconductor device according to the first example embodiment.

FIG. 7 is a cross-sectional view showing a step of the method for fabricating the semiconductor device according to the first example embodiment.

FIG. 8 is a cross-sectional view showing a step of the method for fabricating the semiconductor device according to the first example embodiment.

FIG. 9 is a cross-sectional view showing a step of the method for fabricating the semiconductor device according to the first example embodiment.

FIGS. 10A and 10B are cross-sectional views each showing a step of the method for fabricating the semiconductor device according to the first example embodiment, of which FIG. 10A is a process view associated with a cross-sectional structure along the line P-P′ of FIG. 1A, and FIG. 10B is a process view associated with a cross-sectional structure along the line Q-Q′ of FIG. 1A.

FIGS. 11A and 11B are cross-sectional views each showing a step of the method for fabricating the semiconductor device according to the first example embodiment, of which FIG. 11A is a process view associated with the cross-sectional structure along the line P-P′ of FIG. 1A, and FIG. 11B is a process view associated with the cross-sectional structure along the line Q-Q′ of FIG. 1A.

FIGS. 12A and 12B are cross-sectional views each showing a step of the method for fabricating the semiconductor device according to the first example embodiment, of which FIG. 12A is a process view associated with the cross-sectional structure along the line P-P′ of FIG. 1A, and FIG. 12B is a process view associated with the cross-sectional structure along the line Q-Q′ of FIG. 1A.

FIGS. 13A and 13B are cross-sectional views each showing a step of the method for fabricating the semiconductor device according to the first example embodiment, of which FIG. 13A is a process view associated with the cross-sectional structure along the line P-P′ of FIG. 1A, and FIG. 13B is a process view associated with the cross-sectional structure along the line Q-Q′ of FIG. 1A.

FIG. 14 is a cross-sectional view showing a step of a method for fabricating the semiconductor device according to the second example embodiment.

FIGS. 15A and 15B are cross-sectional views each showing a step of the method for fabricating the semiconductor device according to the second example embodiment, of which FIG. 15A is a process view associated with a cross-sectional structure along the line P-P′ of FIG. 1A, and FIG. 15B is a process view associated with a cross-sectional structure along the line Q-Q′ of FIG. 1A.

FIGS. 16A and 16B are cross-sectional views each showing a step of the method for fabricating the semiconductor device according to the second example embodiment, of which FIG. 16A is a process view associated with the cross-sectional structure along the line P-P′ of FIG. 1A, and FIG. 16B is a process view associated with the cross-sectional structure along the line Q-Q′ of FIG. 1A.

FIG. 17 is a cross-sectional view showing a step of a method for fabricating the semiconductor device according to the third example embodiment.

FIGS. 18A and 18B are cross-sectional views each showing a step of the method for fabricating the semiconductor device according to the third example embodiment, of which FIG. 18A is a process view associated with a cross-sectional structure along the line P-P′ of FIG. 1A, and FIG. 18B is a process view associated with a cross-sectional structure along the line Q-Q′ of FIG. 1A.

FIGS. 19A and 19B are cross-sectional views each showing a step of the method for fabricating the semiconductor device according to the third example embodiment, of which FIG. 19A is a process view associated with the cross-sectional structure along the line P-P′ of FIG. 1A, and FIG. 19B is a process view associated with the cross-sectional structure along the line Q-Q′ of FIG. 1A.

FIG. 20A is an overall cross-sectional view of a conventional N-channel trench MISFET, FIG. 20B is a plan view of a peripheral portion R_{C} of the conventional N-channel trench MISFET, and FIG. 20C is a cross-sectional view of the peripheral portion R_{C} of the conventional N-channel trench MISFET.

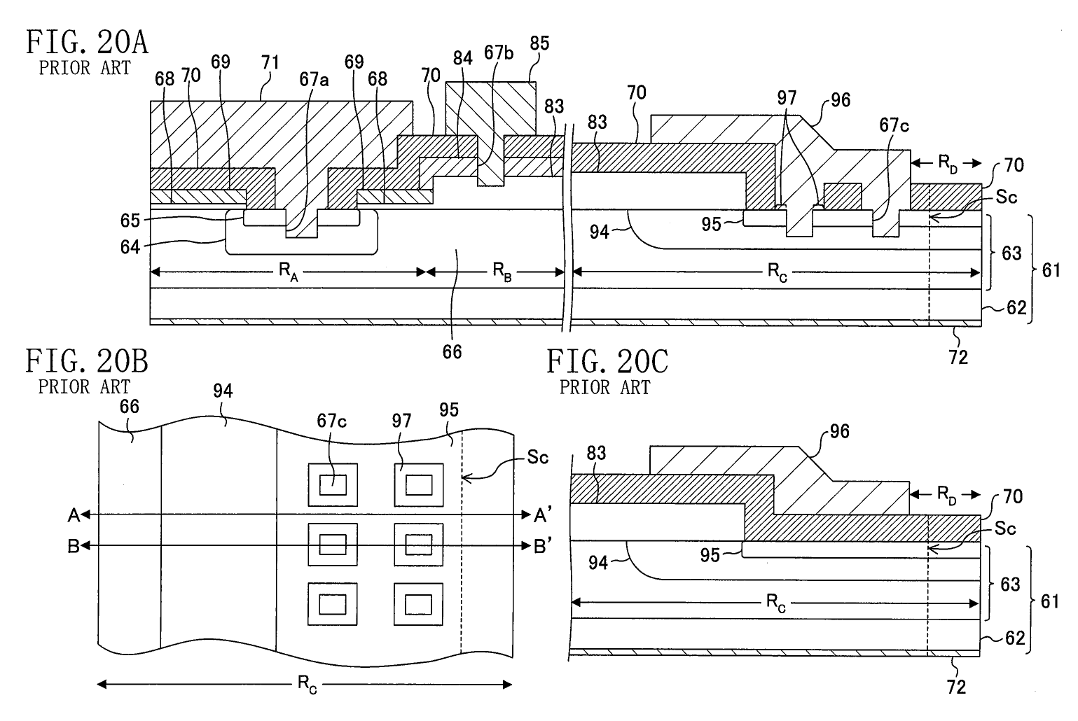

### DETAILED DESCRIPTION

### First Example Embodiment

Referring to the drawings, a semiconductor device according to a first example embodiment of the present disclosure and a method for fabricating the same will be described below.

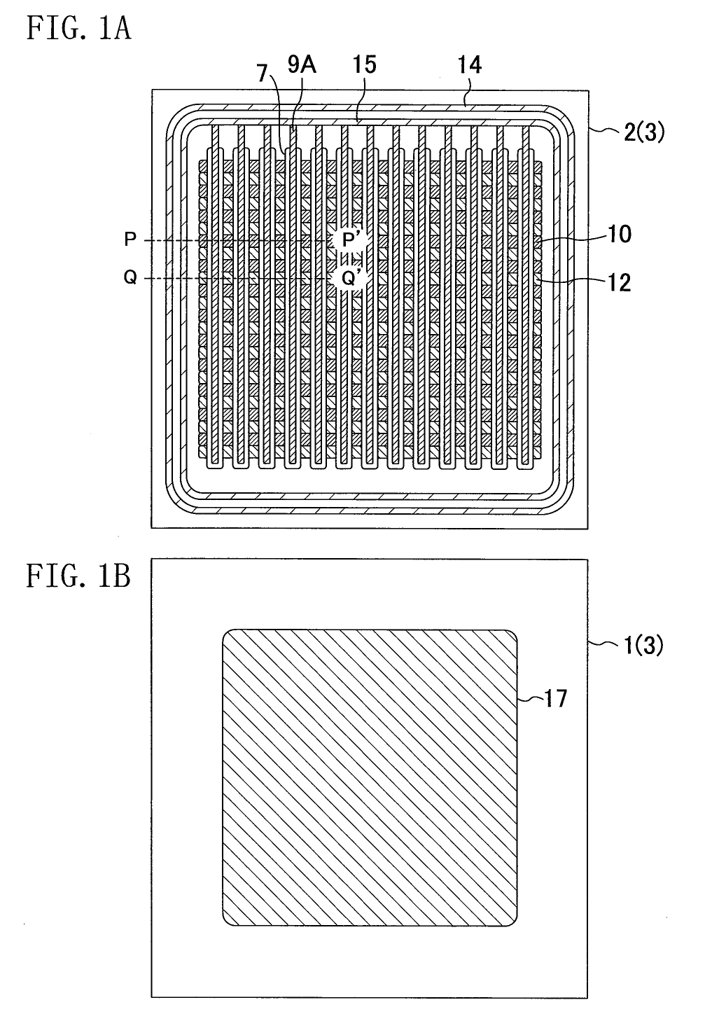

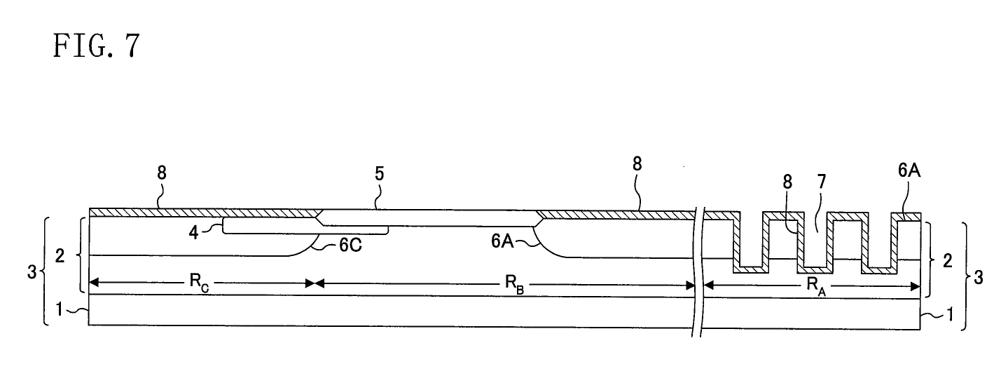

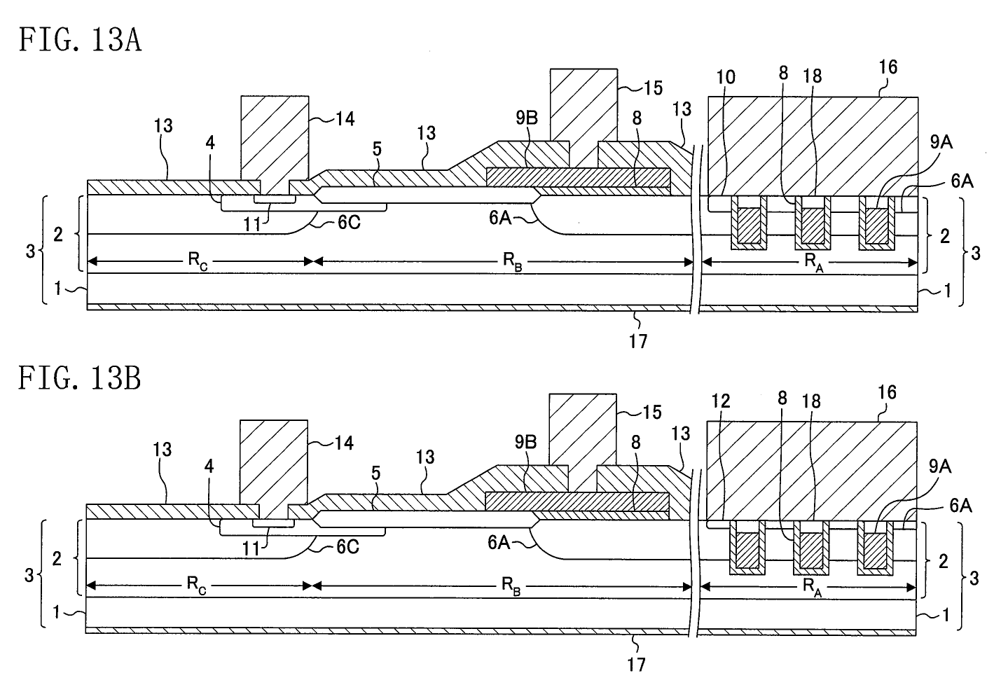

FIGS. 1A and 1B are a top-side plan view and a back-side plan view of the semiconductor device according to the first example embodiment. As shown in FIGS. 1A and 1B, an epitaxial layer 2 containing an N-type impurity at a low concentration is formed on the top surface of an N-type semiconductor substrate 1 (the semiconductor substrate 1 and the epitaxial layer 2 form a semiconductor substrate 3). The impurity concentration of the epitaxial layer 2 is lower than that of the semiconductor substrate 1. On the epitaxial layer 2, a ring-shaped EQR electrode 14 is formed along the periphery of a chip, and a ring-shaped gate electrode 15 is formed on the portion of the epitaxial layer 2 located inwardly of the EQR electrode 14. In the portion of the epitaxial layer 2 located inwardly of the gate electrode 15, formed are a plurality of buried gate electrodes 9A each having an rectangular strip-like shape, and electrically connected to the gate electrode 15. The buried gate electrodes 9A are buried in individual trenches 7 formed to extend through a first well region 6A (see FIG. 7) provided in the epitaxial layer 2. In the surface portion of the epitaxial layer 2 located inwardly of the gate electrode 15, formed are a plurality of body contact regions 10 and source regions 12 each having a rectangular strip-like shape, which are alternately arranged so as to be orthogonal to each of the buried gate electrodes 9A. Note that, at the back surface of the semiconductor substrate 1 (semiconductor substrate 3), formed is a drain electrode 17. In FIGS. 1A and 1B, for clear illustration of the layout of principal components, the depiction of part of components such as a source electrode 16 and an insulating film 18 (see FIGS. 13A and 13B) is omitted.

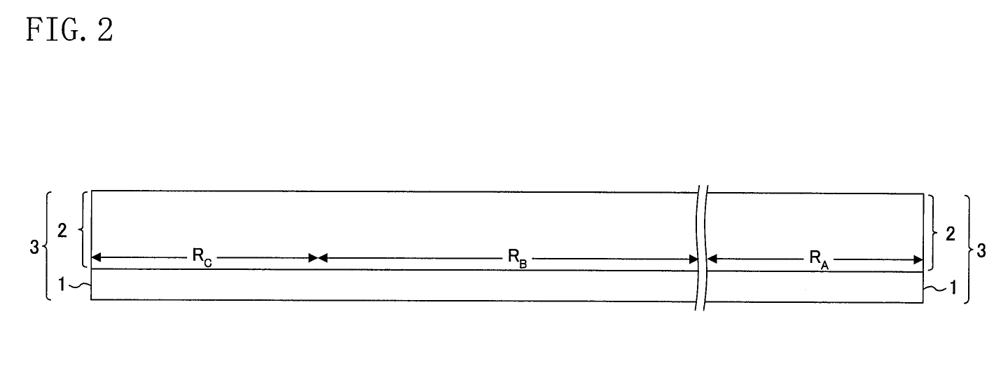

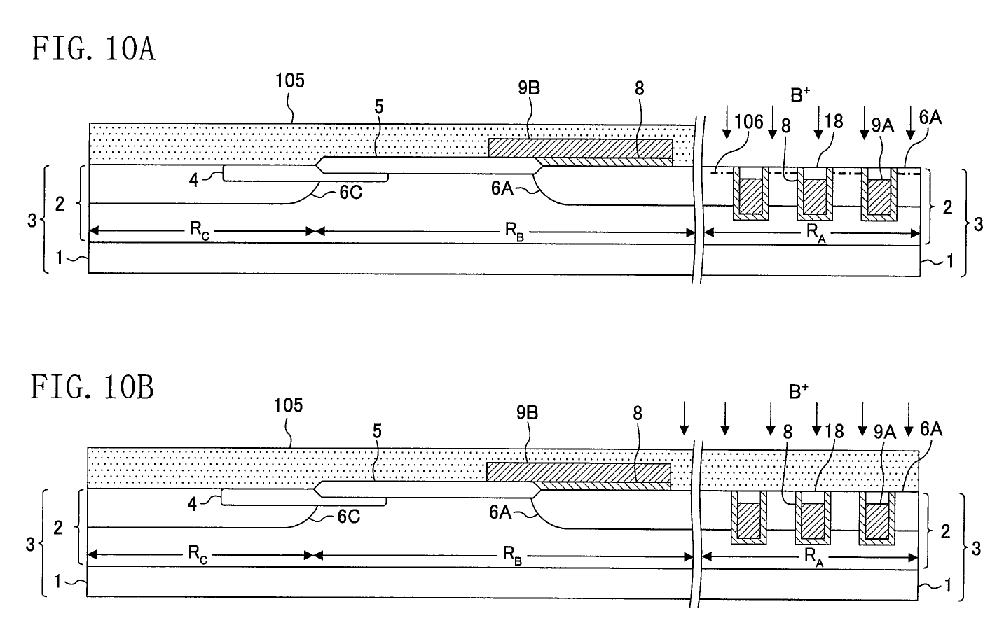

FIGS. 2-9, 10A, 10B, 11A, 11B, 12A, 12B, 13A, and 13B are cross-sectional views each showing a step of the method for fabricating the semiconductor device according to the first example embodiment, of which FIGS. 10A, 11A, 12A, and 13A are process views each associated with a cross-sectional structure along the line P-P′ of FIG. 1A, and FIGS. 10B, 11B, 12B, and 13B are process views each associated with a cross-sectional structure along the line Q-Q′ of FIG. 1A. For each of the steps shown in FIGS. 2-9, the cross-sectional structure along the line P-P′ of FIG. 1A and the cross-sectional structure along the line Q-Q′ of FIG. 1A are the same.

First, as shown in FIG. 2, the N-type epitaxial layer 2 containing an N-type impurity at a concentration lower than that of the N-type semiconductor substrate 1 is grown on the top surface of the semiconductor substrate 1 to a thickness of about 3 μm to form the semiconductor substrate 3 including the semiconductor substrate 1 and the epitaxial layer 2. Note that, in the first example embodiment, the semiconductor device is fabricated by two-dimensionally dividing the semiconductor substrate 3 into an element portion R_{A} having a vertical element, a peripheral portion R_{C} surrounding the element portion R_{A}, and a field portion R_{B} interposed between the element portion R_{A} and the peripheral portion R_{C}. An impurity species in the N-type semiconductor substrate 1 is arsenic, and the concentration thereof is 1×10¹⁹/cm³. An impurity species in the N-type epitaxial layer 2 is phosphorus, and the concentration thereof is 3×10¹⁶/cm³.

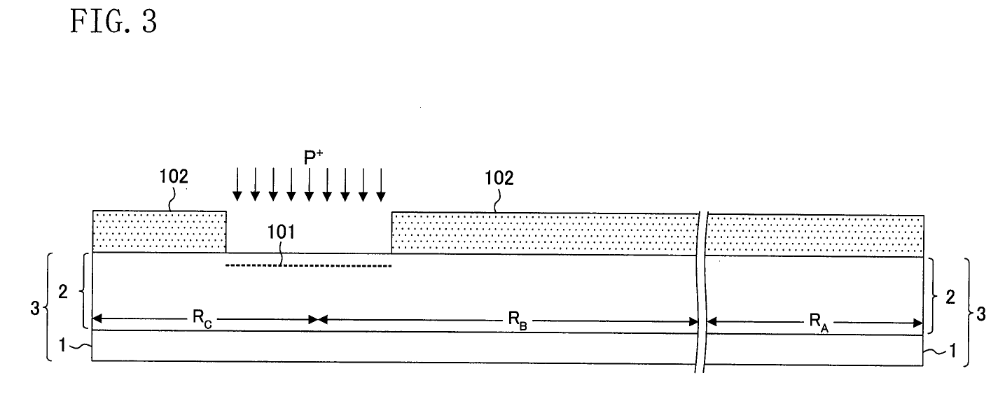

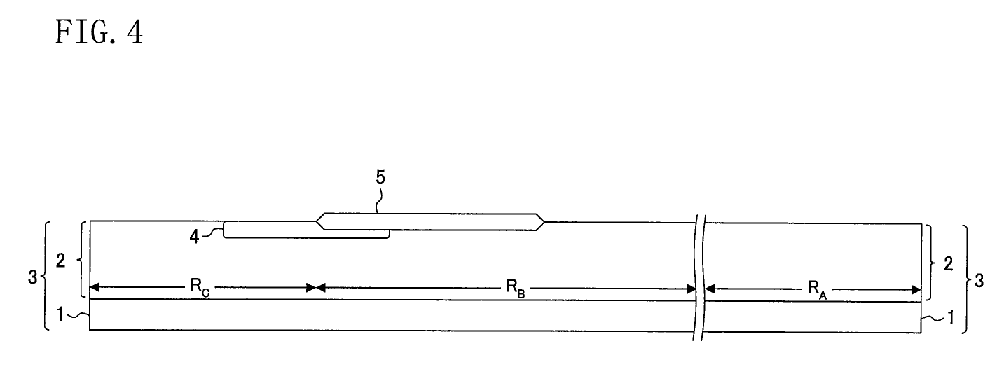

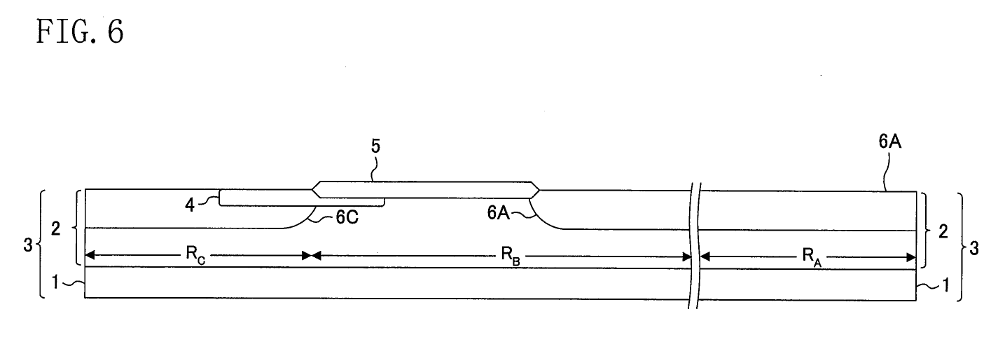

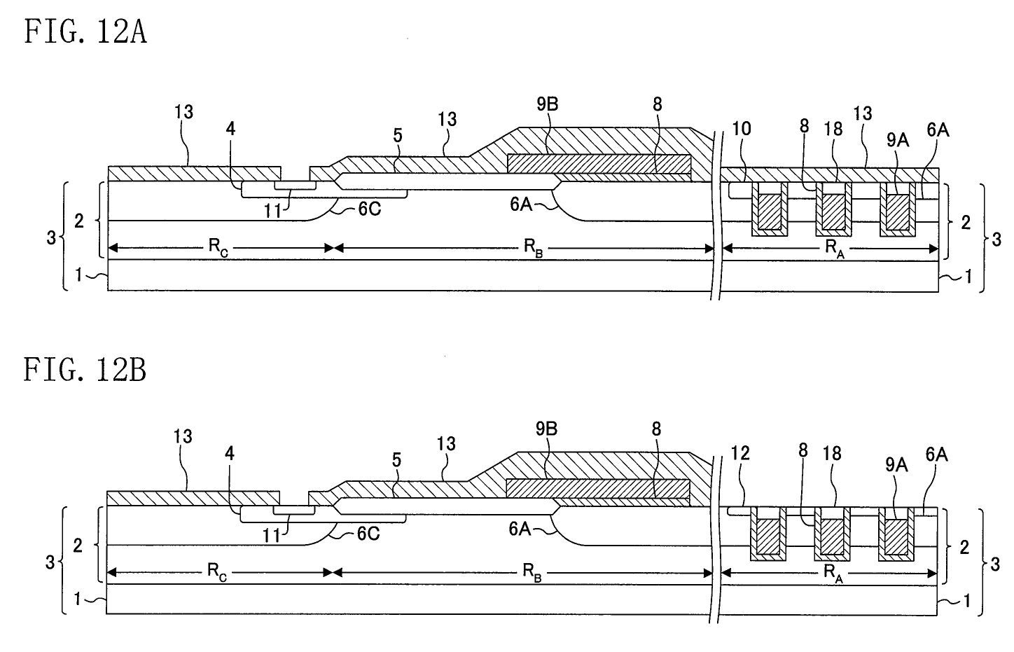

Next, as shown in FIG. 3, impurity implantation is performed in order to form an N-type depletion stop region 4 (see FIG. 4) for suppressing the occurrence of a leakage current flowing between the element portion R_{A} and the peripheral portion R_{C}, which characterizes the first example embodiment. Specifically, after the entire top surface of the semiconductor substrate 3 is coated with a photoresist 102, the portion of the photoresist 102 located at the position where the depletion stop region 4 is to be formed is removed to form an opening. Then, using the photoresist 102 as a mask, N-type impurity ions are implanted into the surface portion of the semiconductor substrate 3, thereby forming an N-type impurity implanted layer 101 having an impurity peak concentration at a position at a depth of about 0.2 μm from the top surface of the semiconductor substrate 3, and serving as the depletion stop region 4. Examples of implantation conditions used at this time are such that an implanted impurity is phosphorus, an implantation energy is 150 keV, and an amount of the implanted impurity (dose) is 1×10¹³/cm². As for the opening provided in the photoresist 102, it is sufficient for the left end (end closer to the end portion of a chip) thereof to partially overlap a channel stopper region 11 (see FIGS. 12A and 12B) formed later, and the channel stopper region 11 need not necessarily be included in the opening. On the other hand, it is necessary for the right end (end located inwardly in the chip) of the opening provided in the photoresist 102 to be located further inwardly of the right end of the channel stopper region 11 in the chip, and located inwardly of the right end (end located inwardly in the chip) of a P-type second well region 6C (see FIG. 6) formed later by a given distance (not particularly limited) in the chip.

Next, after the photoresist 102 is removed, the top surface portion of the semiconductor substrate 3 located in the area other than the area where a field insulating film is to be formed is masked with a silicon nitride film, although the depiction thereof is omitted, and known thermal oxidation is performed to form a field insulating film 5 on the portion of the semiconductor substrate 3 located in the field portion R_{B}, as shown in FIG. 4. At this time, by the foregoing thermal oxidation, the impurity in the N-type impurity implanted layer 101 is thermally diffused to form the N-type depletion stop region 4. Note that the thermal oxidation is performed under temperature conditions of, e.g., 1050° C. for 30 minutes. The impurity concentration of the N-type depletion stop region 4 is, e.g., 4×10¹⁷/cm³. That is, the impurity concentration of the N-type depletion stop region 4 is higher than the impurity concentration of the N-type epitaxial layer 2. Note that, in the first example embodiment, the depletion stop region 4 is formed so as to extend from under the field insulating film 5 in the vicinity of the peripheral portion R_{C} to the epitaxial layer 2 in the peripheral portion R_{C}.

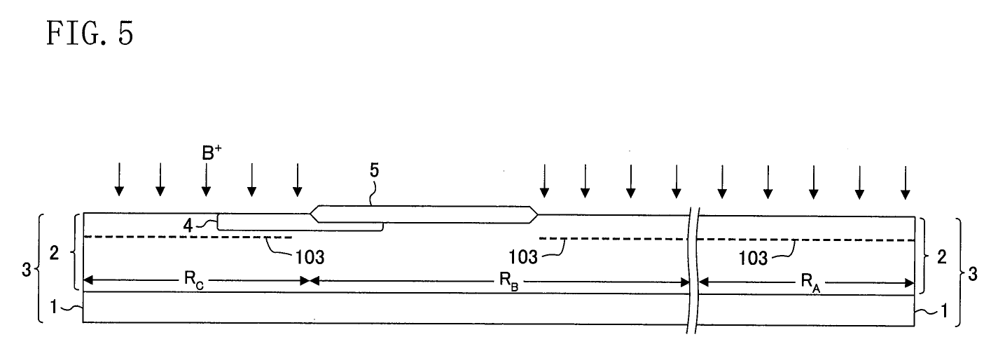

Next, as shown in FIG. 5, in order to form the P-type well regions 6A and 6C (see FIG. 6) described later, P-type impurity ions are implanted in the entire surface of the semiconductor substrate 3 using the field insulating film 5 as a mask, thereby forming impurity implanted layers 103 each having an impurity peak concentration at a position at a depth of about 0.5 μm from the top surface of the semiconductor substrate 3, and respectively serving as the well regions 6A and 6C. Examples of implantation conditions used at this time are such that an implanted impurity is boron, an implantation energy is 150 keV, and an amount of the implanted impurity (dose) is 4×10¹³/cm².

Next, as shown in FIG. 6, the impurity in the P-type impurity implanted layers 103 is thermally diffused by a known thermal process such that the P-type first well region 6A is formed in the portion of the epitaxial layer 2 located in the element portion R_{A} to come in contact with the field insulating film 5 and that the P-type second well region 6C is formed in the portion of the epitaxial layer 2 located in the peripheral portion R_{C} so as to adjoin the field insulating film 5 with the depletion stop region 4 interposed therebetween. At this time, the thermal process is performed under temperature conditions of, e.g., 900° C. for 30 minutes. The impurity concentration of each of the well regions 6A and 6C is, e.g., 2×10¹⁷/cm³. Note that, in the first example embodiment, the second well region 6C is formed so as to surround the depletion stop region 4 in the peripheral portion R_{C}. In other words, the depletion stop region 4 is formed so as to extend into the second well region 6C. Also in the first example embodiment, the first well region 6A is formed so as to extend to the portion of the epitaxial layer 2 located in a predetermined region of the field portion R_{B} (part of the field portion R_{B}) closer to the element portion R_{A} by not forming the field insulating film 5 in the predetermined region.

Next, as shown in FIG. 7, the gate electrode formation region of the epitaxial layer 2 located in the element portion R_{A} is selectively etched using a known technique so that the plurality of trenches 7 are formed to extend through the first well region 6A and reach the epitaxial layer 2 under the first well region 6A. Subsequently, known thermal oxidation is performed to form a gate insulating film 8 made of a silicon dioxide film having a uniform thickness on each of the exposed portions of the semiconductor substrate 3, i.e., on each of the inner walls of the trenches 7 and the first well region 6A in the element portion R_{A}, on the first well region 6A in the field portion R_{B}, and on each of the depletion stop region 4 and the second well region 6C in the peripheral portion R_{C}. Here, the depth and width of each of the trenches 7 after the formation of the gate insulating film 8 are, e.g., 1.0 μm and 0.4 μm. At this time, the thermal oxidation is performed under temperature conditions of, e.g., 950° C. for 30 minutes.

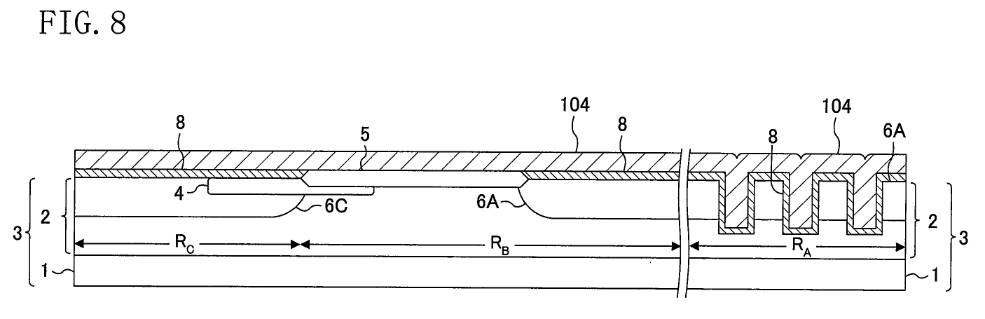

Next, as shown in FIG. 8, a polysilicon film 104 is uniformly deposited over the entire surface of the semiconductor substrate 3 to be buried in each of the trenches 7 with no gap therebetween. Note that the polysilicon film 104 has a thickness of, e.g., 500 nm, and is doped with phosphorus as an impurity at a concentration of 1×10²¹/cm³ or more.

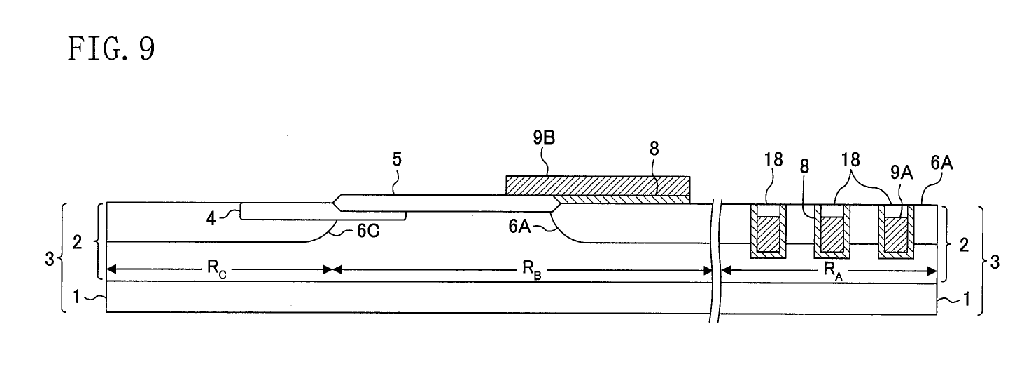

Next, the region in the field portion R_{B} (the predetermined region in the field portion R_{B} adjoining the portion of the field insulating film 5 adjacent to the element portion R_{A} and the portion of the field insulating film 5 adjacent to the predetermined region) where a gate polysilicon layer is to be formed is masked, although the depiction thereof is omitted, and the polysilicon film 104 is etched using a known dry etching technique. Then, the exposed gate insulating film 8 is etched, whereby a gate polysilicon layer 9B is formed on the portion of the gate insulating film 8 located on the first well region 6A in the field portion R_{B} and on the portion of the field insulating film 5 adjacent thereto, as shown in FIG. 9. At this time, in the peripheral portion R_{C}, polysilicon film 104 and the gate insulating film 8 are completely removed by etching. Note that, in the first example embodiment, the gate polysilicon layer 9B functions as a part of the gate electrode 15 (see FIGS. 13A and 13B) formed thereon, and is formed in a ring-shaped configuration in the peripheral portion R_{C} so as to transmit a gate voltage applied from the outside to the buried gate electrode 9A buried in each of the trenches 7. When the gate polysilicon layer 9B is formed, the polysilicon film 104 remains only in each of the trenches 7 in the element portion R_{A}, and the buried gate electrode 9A is formed over the wall surface of each of the trenches 7 with the gate insulating film 8 interposed therebetween. The buried gate electrodes 9A are connected to the gate polysilicon layer 9B in the peripheral portion R_{C}. Note that, in the element portion R_{A} also, the polysilicon film 104 and the gate insulating film 8 on the top surface of the semiconductor substrate 3 are completely removed by etching. The portion of the buried polysilicon film 104 located in an upper portion of each of the trenches 7 is removed by etching together with the gate insulating film 8, and the insulating film 18 is buried in each of the resultant recessed portions, as shown in FIG. 9.

Next, as shown in FIG. 10A associated with the cross-sectional structure along the line P-P′ of FIG. 1 A in which the body contact regions 10 (see FIG. 12A) are to be formed in the subsequent step, P-type impurity ions are implanted into surface portions of the first well region 6A using a photoresist 105 having openings corresponding to the areas where the body contact regions 10 are to be formed as a mask to form P-type impurity implanted layers 106 each having an impurity peak concentration at a position at a depth of about 0.15 μm from the top surface of the semiconductor substrate 3, and serving as the body contact regions 10. Examples of implantation conditions used at this time are such that an implanted impurity is boron, an implantation energy is 40 keV, and an amount of the implanted impurity (dose) is 5×10¹⁵/cm². As shown in FIG. 10B associated with the cross-sectional structure along the line Q-Q′ of FIG. 1A in which the source regions 12 (see FIG. 12B) are to be formed in the subsequent step, when the step shown in FIG. 10A is performed, the photoresist 105 covering the entire surfaces of the areas where the source regions 12 are to be formed prevents the P-type impurity ion from being implanted in the surface portion of the first well region 6A.

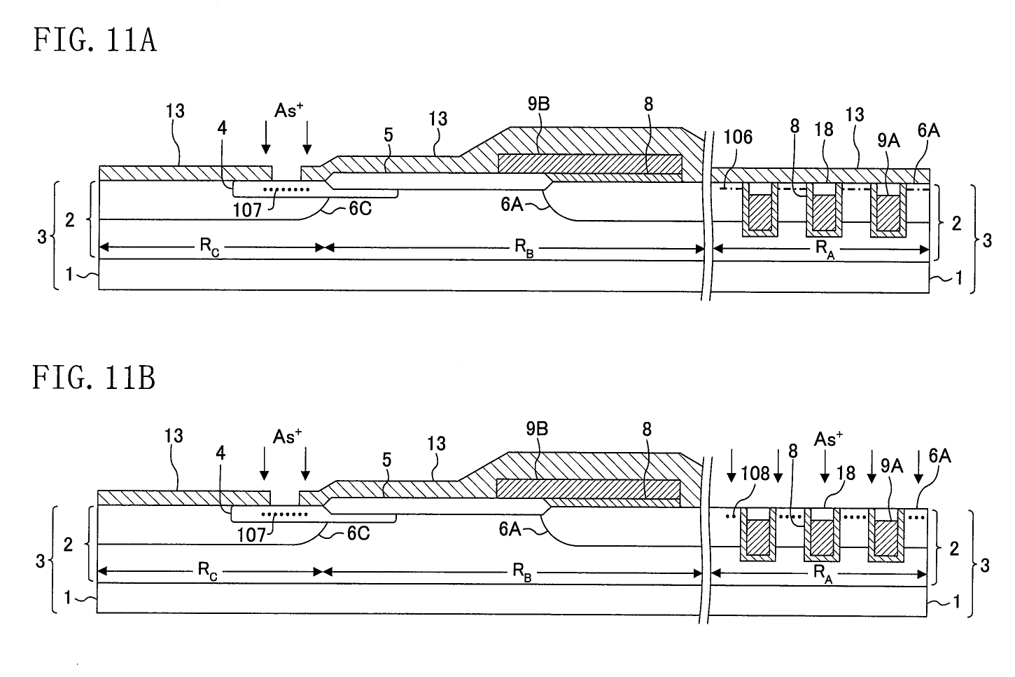

Next, an interlayer insulating film 13 is formed over the entire top surface of the semiconductor substrate 3, although the depiction thereof is omitted. Then, as shown in FIG. 11B associated with the cross-sectional structure along the line Q-Q′ of FIG. 1A, the respective portions of the interlayer insulating film 13 located in the areas where the source regions 12 are to be formed and in the area where the channel stopper region 11 (see FIG. 12A) is to be formed are removed by a known etching technique to form openings. Thereafter, N-type impurity ions are implanted in the surface portions of the semiconductor substrate 3 through the openings. In this manner, an N-type impurity implanted layer 107 and N-type impurity implanted layers 108 each having an impurity peak concentration at a position at a depth of about 0.03 μm from the top surface of the semiconductor substrate 3, and respectively serving as the channel stopper region 11 and the source regions 12 are formed. Examples of implantation conditions used at this time are such that an implanted impurity is arsenic, an implantation energy is 30 keV, and an amount of the implanted impurity (dose) is 3×10¹⁵/cm². At the same time as the step shown in FIG. 11B, as shown in FIG. 11A associated with the cross-sectional structure along the line P-P′ of FIG. 1 A in which the P-type impurity implanted layers 106 serving as the body contact regions 10 have been formed in the preceding step, only the portion of the interlayer insulating film 13 located in the area where the channel stopper region 11 is to be formed is removed by a known etching technique to form the opening. Then, N-type impurity ions are implanted in the surface portion of the semiconductor substrate 3 through the opening. That is, concerning the cross-sectional structure along the line P-P′ of FIG. 1A, the portions of the element portion R_{A} located in the areas where the body contact regions 10 are to be formed are covered with the interlayer insulating film 13 so that only the N-type impurity implanted layer 107 serving as the channel stopper region 11 is formed.

Next, as shown in FIG. 12A associated with the cross-sectional structure along the line P-P′ of FIG. 1A, the impurity in the P-type impurity implanted layers 106 serving as the body contact regions 10 and the impurity in the N-type impurity implanted layer 107 serving as the channel stopper region 11 are each diffused by a known thermal process using, e.g., rapid thermal annealing (RTA) to form the P-type body contact regions 10 and the N-type channel stopper region 11. At the same time as the step shown in FIG. 12A, as shown in FIG. 12B associated with the cross-sectional structure along the line Q-Q′ of FIG. 1A, the impurity in the N-type impurity implanted layers 108 serving as the source regions 12 and the impurity in the N-type impurity implanted layer 107 serving as the channel stopper region 11 are each diffused by the foregoing thermal process to form the N-type source regions 12 and the N-type channel stopper region 11. That is, in the element portion R_{A}, the N-type source regions 12 are formed in the surface portions of the P-type first well region 6A so as to adjoin the buried gate electrodes 9A, while the P-type body contact regions 10 are formed in the surface portions of the P-type first well region 6A so as to adjoin each of the buried gate electrodes 9A and the source regions 12. At this time, the thermal process is performed under temperature conditions of, e.g., 1000° C. for 10 seconds. The respective impurity concentrations of the body contact regions 10, the source regions 12, and the channel stopper region 11 are, e.g., 1×10²⁰/cm³. That is, the impurity concentration of the N-type channel stopper region 11 is higher than the impurity concentration of the N-type depletion stop region 4, and the impurity concentrations of the P-type body contact regions 10 are higher than the impurity concentration of the P-type first well region 6A. Note that, in the first example embodiment, the channel stopper region 11 is formed in the surface portion of the depletion stop region 4 located in the second well region 6C to be surrounded by the depletion stop region 4.

Next, as shown in FIG. 13A associated with the cross-sectional structure along the line P-P′ of FIG. 1A, the portions of the interlayer insulating film 13 located in the areas where the body contact regions 10 are formed are removed, and the portion of the interlayer insulating film 13 located on the gate polysilicon layer 9B is removed to form openings. Then, a conductive film made of, e.g., an aluminum film is deposited over the entire top surface of the semiconductor substrate 3. Thereafter, by patterning the conductive film, the EQR electrode 14 electrically connected to the channel stopper region 11, the gate electrode 15 electrically connected to the gate polysilicon layer 9B, and the source electrode 16 electrically connected to the body contact regions 10 are formed individually. At the same time as the step shown in FIG. 13A, as shown in FIG. 13B associated with the cross-sectional structure along the line Q-Q′ of FIG. 1A, the portion of the interlayer insulating film 13 located on the gate polysilicon layer 9B is removed to form the opening. Then, by patterning the conductive film, the EQR electrode 14 electrically connected to the channel stopper region 11, the gate electrode 15 electrically connected to the gate polysilicon layer 9B, and the source electrode 16 electrically connected to the source regions 12 are formed individually. Thereafter, as shown in each of FIGS. 13A and 13B associated with the respective cross-sectional structures along the lines P-P′ and Q-Q′ of FIG. 1A, the drain electrode 17 made of, e.g., an aluminum film is formed on the back surface of the semiconductor substrate 3 (semiconductor substrate 1), whereby the semiconductor device according to the first example embodiment is completed. That is, in the semiconductor device (specifically the vertical element provided in the element portion R_{A}) according to the first example embodiment, when a predetermined voltage is applied to the source electrode 16 to apply a gate voltage to the buried gate electrode 9A buried in each of the trenches 7, a channel is formed along the wall surface of the trench 7 in the first well region 6A, and a drain current flows from the source regions 12 toward the area of the semiconductor substrate 1 serving as the drain region via the channel.

As described above, in the first example embodiment, the N-type channel stopper region 11 having a concentration of the order of, e.g., 1×10²⁰/cm³ is formed in the portion of the N-type epitaxial layer 2 having a concentration of the order of, e.g., 1×10¹⁶/cm³ which is located in the peripheral portion R_{C}, and the N-type depletion stop region 4 having a concentration (of the order of e.g., 1×10¹⁷/cm³) higher than that of the epitaxial layer 2 is formed so as to surround the channel stopper region 11, and extend further inwardly of the channel stopper region 11 in the chip (i.e., extend under the field insulating film 5). Here, the depletion stop region 4 need not extend to the peripheral end of the chip as long as it partially overlaps the channel stopper region 11.

In such a structure according to the first example embodiment, even when ions that have entered the device from the outside thereof in a temperature cycle test are fixed in the field insulating film 5, and the top surface portion (i.e., the epitaxial layer 2) of the semiconductor substrate 3 in the field portion R_{B} is locally depleted, the formation of a depletion layer over the entire top surface of the epitaxial layer 2 from the element portion R_{A} to the peripheral portion R_{C} is suppressed. Therefore, in the insulated gate semiconductor device after the temperature cycle test, it is possible to suppress a leakage current from flowing between the element portion R_{A} and the peripheral portion R_{C}. Specifically, it is possible to completely inhibit the occurrence of a leakage current that has been conventionally monitored as a drain current larger than a normal drain current by about two orders of magnitude with a drain voltage lower than a breakdown voltage. In addition, even when the impurity concentration of the epitaxial layer 2 is reduced in response to a future request for a higher breakdown voltage placed on a vertical insulated gate semiconductor device, the depletion stop region 4 allows an increase in breakdown voltage without causing concern about the depletion of the top surface portion of the epitaxial layer 2 in the field portion R_{B}.

In the first example embodiment, the description has been given using the case where the N-channel trench MISFET is formed as the vertical element as an example. However, even when a P-channel trench MISFET is formed instead as the vertical element, the occurrence of a leakage current can be similarly inhibited. In this case, it is appropriate to use the same methods and conditions for forming the field insulating film, the gate insulating film, the gate electrode, and the like as used in the first example embodiment, and invert the conductivity types of impurity species to be implanted into various impurity regions (i.e., switch the conductivity type from the N-type to the P-type and from the P-type to the N-type). That is, by way of example, phosphorus is used for the formation of the well region, boron is used for the formation of the source regions and the channel stopper region, and phosphorus is used for the formation of the body contact regions. In the case of thus forming the P-channel trench MISFET as the vertical element also, even when the surface portion (i.e., the epitaxial layer) of the semiconductor substrate in the field portion R_{B} is locally depleted, the formation of a depletion layer over the entire top surface of the epitaxial layer from the element portion R_{A} to the peripheral portion R_{C} is suppressed. Therefore, in the insulated gate semiconductor device after the temperature cycle test, it is possible to suppress a leakage current from flowing between the element portion R_{A} and the peripheral portion R_{C}. In addition, even when the impurity concentration of the epitaxial layer is reduced in response to a future request for a higher breakdown voltage placed on a vertical insulated gate semiconductor device, the depletion stop region allows an increase in breakdown voltage without causing concern about the depletion of the top surface portion of the epitaxial layer in the field portion R_{B}.

It will be appreciated that various implantation conditions, thermal treatment conditions, impurity concentrations, and the like mentioned in the first example embodiment are only exemplary and that the present disclosure is not limited thereto.

In the first example embodiment, the source electrode 16 has been formed on each of the body contact regions 10 and the source regions 12. Instead, it is also possible that, while the source electrode is formed on the source regions 12, a body electrode separated from the source electrode may be formed on the body contact regions 10.

Alternatively, in the first example embodiment, the vertical element provided in the element portion R_{A} may also be, e.g., a vertical MISFET or a vertical IGBT.

### Second Example Embodiment

Referring to the drawings, a semiconductor device according to a second example embodiment of the present disclosure and a method for fabricating the same will be described below by focusing attention on points different from those in the first example embodiment. Note that the basic plan configuration of the semiconductor device according to the second example embodiment is the same as that of the semiconductor device according to the first example embodiment shown in FIGS. 1A and 1B.

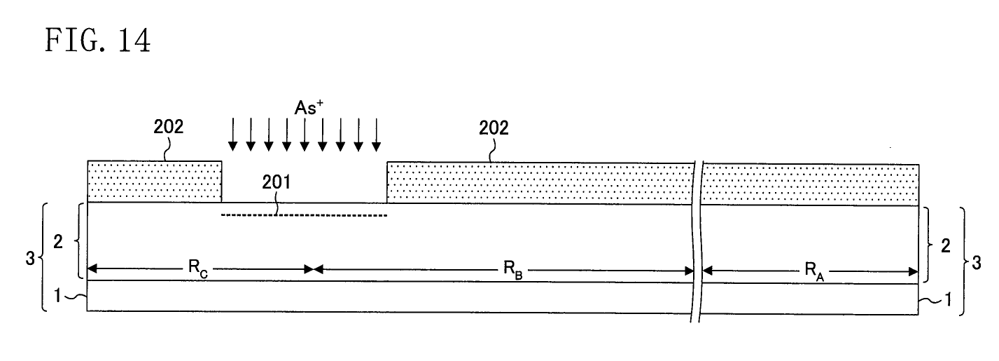

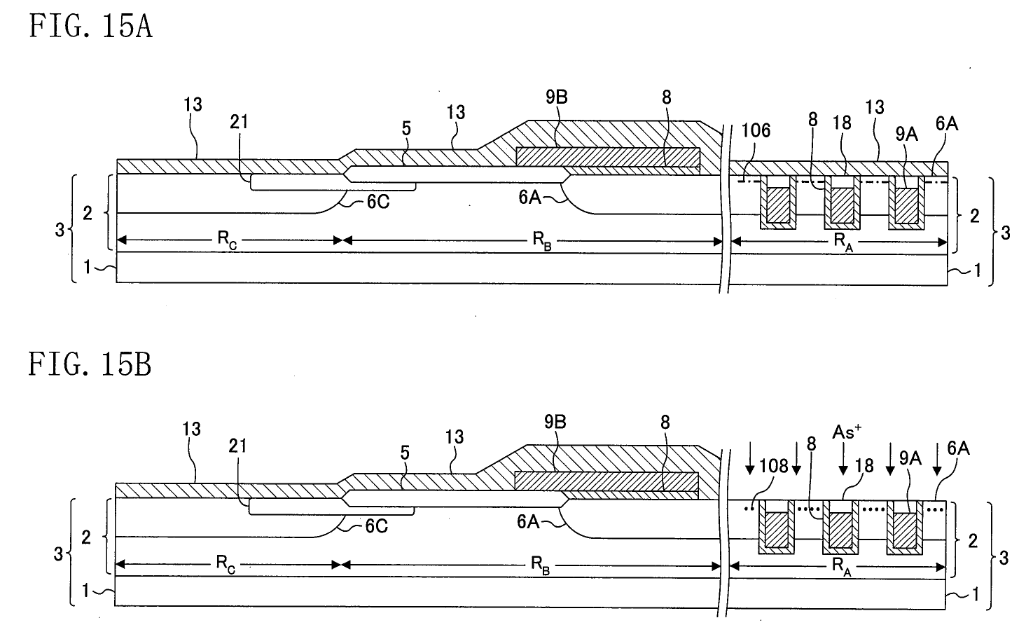

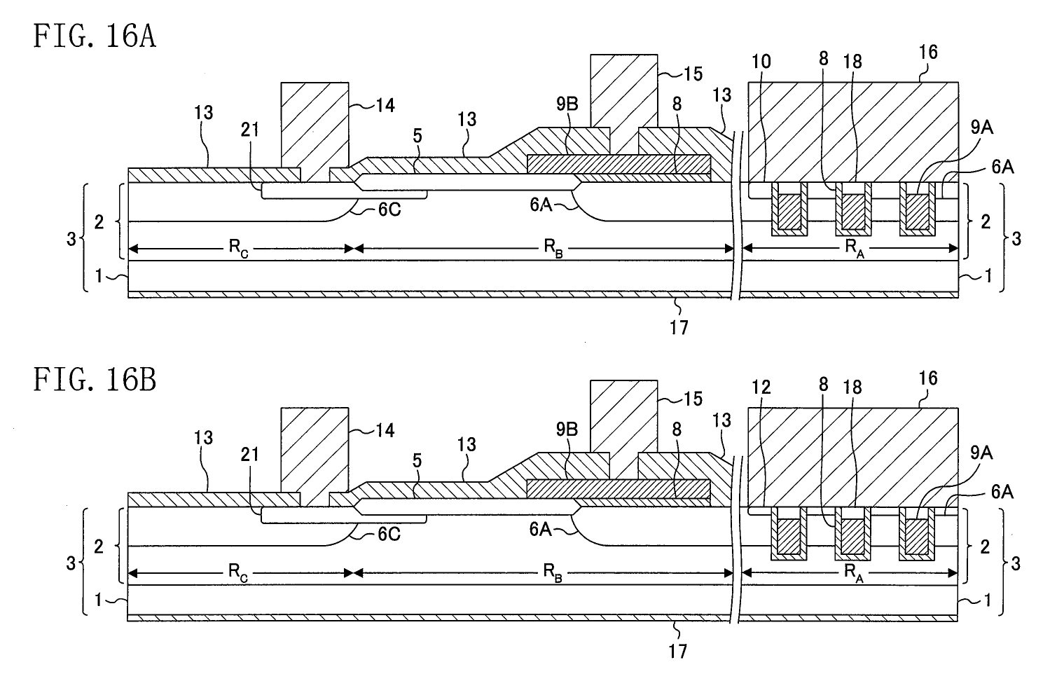

FIGS. 14, 15A, 15B, 16A, and 16B are cross-sectional views each showing a step of the method for fabricating the semiconductor device according to the second example embodiment, of which FIGS. 15A and 16A are process views each associated with a cross-sectional structure along the line P-P′ of FIG. 1A, and FIGS. 15B and 16B are process views each associated with a cross-sectional structure along the line Q-Q′ of FIG. 1A. For the step shown in FIG. 14, the respective cross-sectional structures along the lines P-P′ and Q-Q′ of FIG. 1A are the same. Note that, in FIGS. 14, 15A, 15B, 16A, and 16B, the same components as those of the first example embodiment shown in FIGS. 1A, 1B, 2-9, 10A, 10B, 11A, 11B, 12A, 12B, 13A, and 13B are provided with the same reference numerals, and a repeated description thereof will be omitted.

First, the step shown in FIG. 2 of the first example embodiment is performed. Then, as shown in FIG. 14, impurity implantation is performed in order to form an N-type depletion stop region 21 (see FIGS. 15A and 15B) for suppressing the occurrence of a leakage current flowing between the element portion R_{A} and the peripheral portion R_{C}, which characterizes the second example embodiment. Specifically, after the entire top surface of the semiconductor substrate 3 is coated with a photoresist 202, the portion of the photoresist 202 located at the position where the depletion stop region 21 is to be formed is removed to form an opening. Then, using the photoresist 202 as a mask, N-type impurity ions are implanted into the surface portion of the semiconductor substrate 3, thereby forming an N-type impurity implanted layer 201 having an impurity peak concentration at a position at a depth of about 0.03 μm from the top surface of the semiconductor substrate 3, and serving as the depletion stop region 21. Examples of implantation conditions used at this time are such that an implanted impurity is arsenic, an implantation energy is 30 keV, and an amount of the implanted impurity (dose) is 3×10¹⁵/cm². As for the position of the left end (end closer to the end portion of the chip) of the opening provided in the photoresist 202, it is not particularly limited. On the other hand, it is necessary for the right end (end located inwardly in the chip) of the opening provided in the photoresist 202 to be located inwardly of the right end (end located inwardly in the chip) of the P-type second well region 6C (see FIGS. 15A and 15B) formed later by a given distance (not particularly limited) in the chip. Next, the steps shown in FIGS. 4-9, 10A, and 10B according to the first example embodiment are performed. Here, when the step (step of forming the field insulating film 5) shown in FIG. 4 is performed, the impurity in the N-type impurity implanted layer 201 is thermally diffused to form the N-type depletion stop region 21. The impurity concentration of the N-type depletion stop region 21 is on the order of, e.g., 1×10²⁰/cm³. That is, the impurity concentration of the N-type depletion stop region 21 is higher than the impurity concentration of the N-type epitaxial layer 2. Note that, in the second example embodiment, the depletion stop region 21 is formed so as to extend from under the field insulating film 5 in the vicinity of the peripheral portion R_{C} to the epitaxial layer 2 in the peripheral portion R_{C}.

Next, the interlayer insulating film 13 is formed over the entire top surface of the semiconductor substrate 3, although the depiction thereof is omitted. Then, as shown in FIG. 15B associated with the cross-sectional structure along the line Q-Q′ of FIG. 1A, the portions of the interlayer insulating film 13 located in the areas where the source regions 12 (see FIG. 16B) are to be formed are removed by a known etching technique to form openings. Thereafter, N-type impurity ions are implanted in the surface portions of the semiconductor substrate 3 through the openings, thereby forming the N-type impurity implanted layers 108 each having an impurity peak concentration at a position at a depth of about 0.03 μm from the top surface of the semiconductor substrate 3, and serving as the source regions 12. Examples of implantation conditions used at this time are such that an implanted impurity is arsenic, an implantation energy is 30 keV, and an amount of the implanted impurity (dose) is 3×10¹⁵/cm². However, as shown in FIG. 15A associated with the cross-sectional structure along the line P-P′ of FIG. 1A in which the P-type impurity implanted layers 106 serving as the body contact regions 10 (see FIG. 16A) have been formed in the step shown in FIG. 10A according to the first example embodiment, N-type impurity ions are not implanted into the semiconductor substrate 3 since the entire top surface of the semiconductor substrate 3 is covered with the interlayer insulating film 13 when the step shown in FIG. 15B is performed.

Next, the steps shown in FIGS. 12A and 12B according to the first example embodiment are performed. That is, as shown in FIG. 16A associated with the cross-sectional structure along the line P-P′ of FIG. 1 A, the impurity in the P-type impurity implanted layers 106 serving as the body contact regions 10 is diffused by a known thermal process using, e.g., RTA to form the P-type body contact regions 10. At the same time, as shown in FIG. 16B associated with the cross-sectional structure along the line Q-Q′ of FIG. 1A, the impurity in the N-type impurity implanted layers 108 serving as the source regions 12 is diffused by the foregoing thermal process to form the N-type source regions 12. That is, in the element portion R_{A}, the N-type source regions 12 are formed in the surface portions of the P-type first well region 6A so as to adjoin the buried gate electrodes 9A, and the P-type body contact regions 10 are formed in the surface portions of the P-type first well region 6A so as to adjoin each of the buried gate electrodes 9A and the source regions 12. Note that the impurity concentration of each of the body contact regions 10 and the source regions 12 is on the order of, e.g., 1×10²⁰/cm³. That is, the impurity concentrations of the P-type body contact regions 10 are higher than the impurity concentration of the P-type first well region 6A.

Next, as shown in FIG. 16A associated with the cross-sectional structure along the line P-P′ of FIG. 1A, the respective portions of the interlayer insulating film 13 located in the areas where the body contact regions 10 are to be formed, on the gate polysilicon layer 9B, and on the depletion stop region 21 are removed to form openings. Then, a conductive film made of, e.g., an aluminum film is deposited over the entire surface of the semiconductor substrate 3. Thereafter, by patterning the conductive film, the EQR electrode 14 electrically connected to the depletion stop region 21, the gate electrode 15 electrically connected to the gate polysilicon layer 9B, and the source electrode 16 electrically connected to the body contact regions 10 are formed individually. At the same time as the step shown in FIG. 16A, as shown in FIG. 16B associated with the cross-sectional structure along the line Q-Q′ of FIG. 1A, the respective portions of the interlayer insulating film 13 located on the gate polysilicon layer 9B and on the depletion stop region 21 are removed to form openings. Then, by patterning the foregoing conductive film, the EQR electrode 14 electrically connected to the depletion stop region 21, the gate electrode 15 electrically connected to the gate polysilicon layer 9B, and the source electrode 16 electrically connected to the source regions 12 are formed individually. Thereafter, as shown in each of FIGS. 16A and 16B associated with the respective cross-sectional structures along the lines P-P′ and Q-Q′ of FIG. 1A, the drain electrode 17 made of, e.g., an aluminum film is formed on the back surface of the semiconductor substrate 3 (semiconductor substrate 1), whereby the semiconductor device according to the second example embodiment is completed. That is, in the semiconductor device (specifically the vertical element provided in the element portion R_{A}) according to the second example embodiment, when a predetermined voltage is applied to the source electrode 16 to apply a gate voltage to the buried gate electrode 9A buried in each of the trenches 7, a channel is formed along the wall surface of the trench 7 in the first well region 6A, and a drain current flows from the source regions 12 toward the area of the semiconductor substrate 1 serving as the drain region via the channel.

As described above, in the second example embodiment, the N-type depletion stop region 21 having a concentration (concentration of the order of, e.g., 1×10²⁰/cm³) higher than that of the epitaxial layer 2 is formed in the portion of the N-type epitaxial layer 2 having a concentration of the order of, e.g., 1×10¹⁶/cm³ which is located in the peripheral portion R_{C} so as to extend under the field insulating film 5. Here, the depletion stop region 21 need not extend to the peripheral end of the chip as long as it is electrically connected to the EQR electrode 14.

In such a structure according to the second example embodiment, even when ions that have entered the device from the outside thereof in a temperature cycle test are fixed in the field insulating film 5, and the top surface portion (i.e., the epitaxial layer 2) of the semiconductor substrate 3 in the field portion R_{B} is locally depleted, the formation of a depletion layer over the entire top surface of the epitaxial layer 2 from the element portion R_{A} to the peripheral portion R_{C} is suppressed. Therefore, in the insulated gate semiconductor device after the temperature cycle test, it is possible to suppress a leakage current from flowing between the element portion R_{A} and the peripheral portion R_{C}. Specifically, it is possible to completely inhibit the occurrence of a leakage current that has been conventionally monitored as a drain current larger than a normal drain current by about two orders of magnitude with a drain voltage lower than a breakdown voltage. In addition, even when the impurity concentration of the epitaxial layer 2 is reduced in response to a future request for a higher breakdown voltage placed on a vertical insulated gate semiconductor device, the depletion stop region 21 allows an increase in breakdown voltage without causing concern about the depletion of the top surface portion of the epitaxial layer 2 in the field portion R_{B}.

In the second example embodiment, the description has been given using the case where the N-channel trench MISFET is formed as the vertical element as an example. However, even when a P-channel trench MISFET is formed instead as the vertical element, the occurrence of a leakage current can be similarly inhibited. In this case, it is appropriate to use the same methods and conditions for forming the field insulating film, the gate insulating film, the gate electrode, and the like as used in the second example embodiment, and invert the conductivity types of impurity species to be implanted into various impurity regions (i.e., switch the conductivity type from the N-type to the P-type and from the P-type to the N-type). That is, by way of example, phosphorus is used for the formation of the well region, boron is used for the formation of the source regions and the channel stopper region, and phosphorus is used for the formation of the body contact regions. In the case of thus forming the P-channel trench MISFET as the vertical element also, even when the surface portion (i.e., the epitaxial layer) of the semiconductor substrate in the field portion R_{B} is locally depleted, the formation of a depletion layer over the entire top surface of the epitaxial layer from the element portion R_{A} to the peripheral portion R_{C} is suppressed. Therefore, in the insulated gate semiconductor device after the temperature cycle test, it is possible to suppress a leakage current from flowing between the element portion R_{A} and the peripheral portion R_{C}. In addition, even when the impurity concentration of the epitaxial layer is reduced in response to a future request for a higher breakdown voltage placed on a vertical insulated gate semiconductor device, the depletion stop region allows an increase in breakdown voltage without causing concern about the depletion of the top surface portion of the epitaxial layer in the field portion R_{B}.

It will be appreciated that various implantation conditions, thermal treatment conditions, impurity concentrations, and the like mentioned in the second example embodiment are only exemplary and that the present disclosure is not limited thereto.

In the second example embodiment, the source electrode 16 has been formed on each of the body contact regions 10 and the source regions 12. Instead, it is also possible that, while the source electrode is formed on the source regions 12, a body electrode separated from the source electrode may be formed on the body contact regions 10.

Alternatively, in the second example embodiment, the vertical element provided in the element portion R_{A} may also be, e.g., a vertical MISFET or a vertical IGBT.

### Third Example Embodiment

Referring to the drawings, a semiconductor device according to a third example embodiment of the present disclosure and a method for fabricating the same will be described below by focusing attention on points different from those in the first example embodiment. Note that the basic plan configuration of the semiconductor device according to the third example embodiment is the same as that of the semiconductor device according to the first example embodiment shown in FIGS. 1A and 1B.

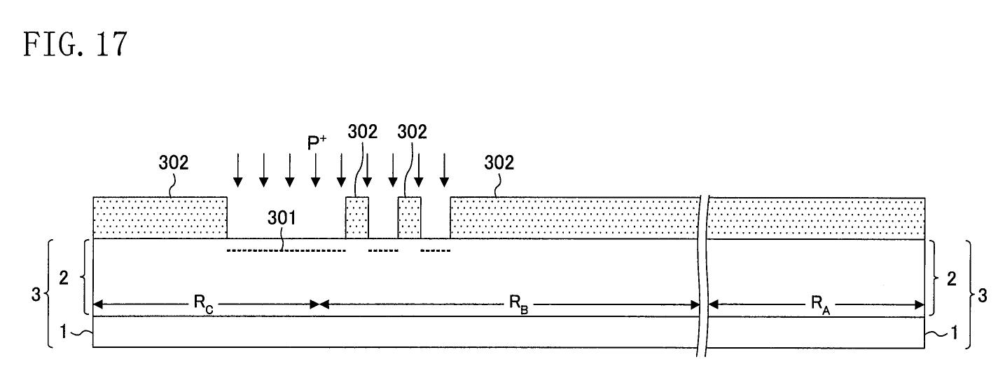

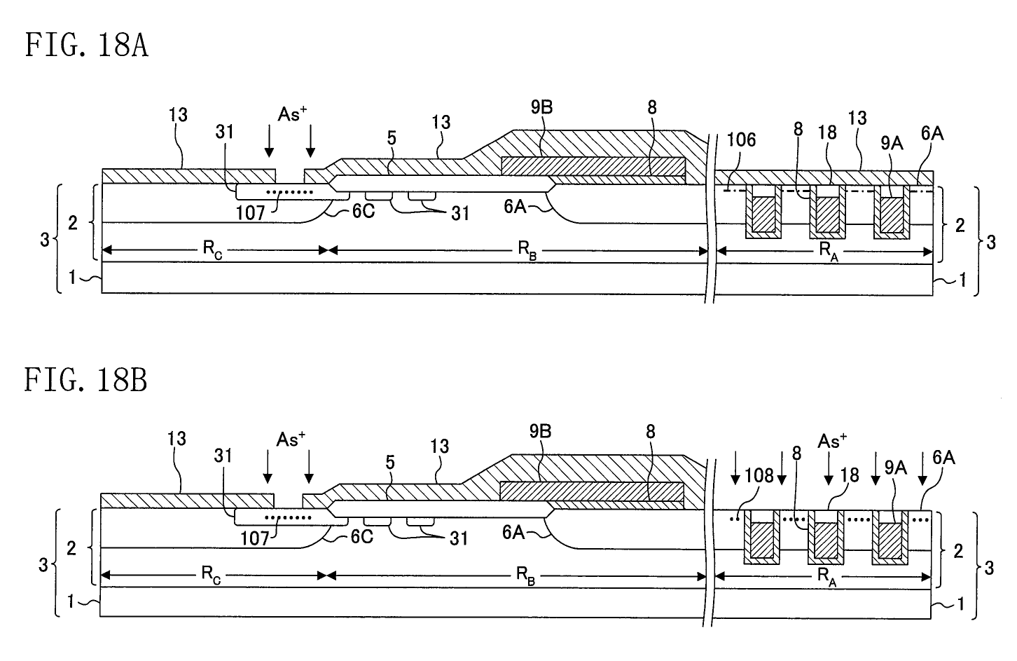

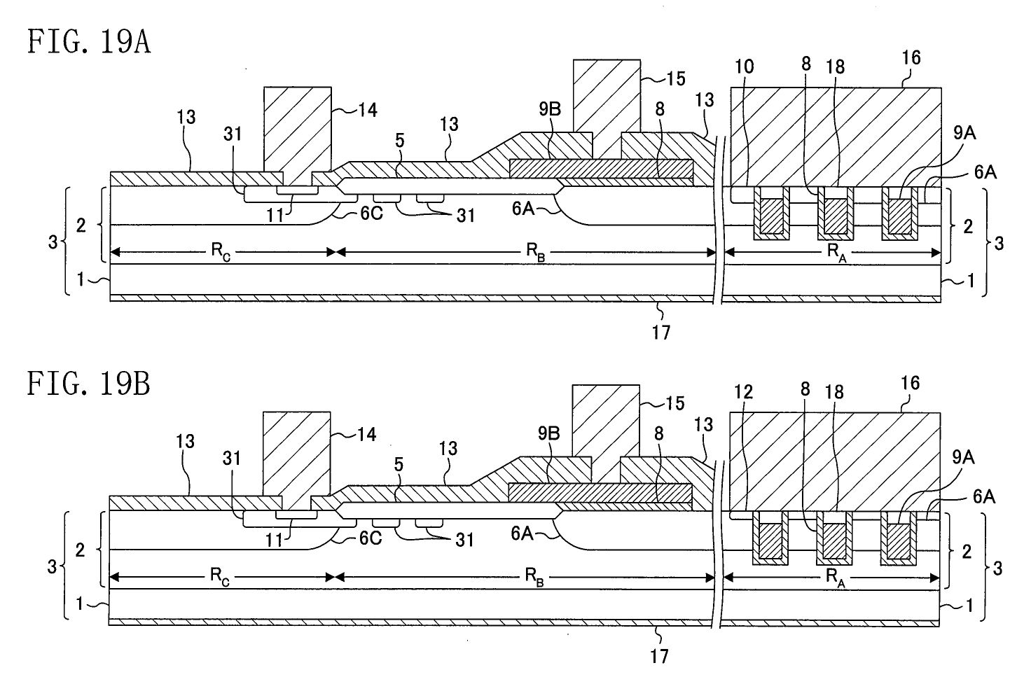

FIGS. 17, 18A, 18B, 19A, and 19B are cross-sectional views each showing a step of the method for fabricating the semiconductor device according to the third example embodiment, of which FIGS. 18A and 19A are process views each associated with a cross-sectional structure along the line P-P′ of FIG. 1A, and FIGS. 18B and 19B are process views each associated with a cross-sectional structure along the line Q-Q′ of FIG. 1A. For the step shown in FIG. 17, the respective cross-sectional structures along the respective lines P-P′ and Q-Q′ of FIG. 1A are the same. Note that, in FIGS. 17, 18A, 18B, 19A, and 19B, the same components as those of the first example embodiment shown in FIGS. 1A, 1B, 2-9, 10A, 10B, 11A, 11B, 12A, 12B, 13A, and 13B are provided with the same reference numerals, and a repeated description thereof will be omitted.

First, the step shown in FIG. 2 of the first example embodiment is performed. Then, as shown in FIG. 17, impurity implantation is performed in order to form an N-type depletion stop region 31 (see FIGS. 18A and 18B) for suppressing the occurrence of a leakage current flowing between the element portion R_{A} and the peripheral portion R_{C}, which characterizes the third example embodiment. Specifically, after the entire top surface of the semiconductor substrate 3 is coated with a photoresist 302, the plurality of portions of the photoresist 302 located at the positions where the depletion stop region 31 is to be formed are removed to form openings. Then, using the photoresist 302 as a mask, N-type impurity ions are implanted into the surface portions of the semiconductor substrate 3, thereby forming N-type impurity implanted layers 301 each having an impurity peak concentration at a position at a depth of about 0.2 μm from the top surface of the semiconductor substrate 3, and serving as the depletion stop region 31. Examples of implantation conditions used at this time are such that an implanted impurity is phosphorus, an implantation energy is 150 keV, and an amount of the implanted impurity (dose) is 1×10¹³/cm². As for the one of the plurality of openings provided in the photoresist 302 closest to the end portion of the chip, it is sufficient for the left end (end closer to the end portion of the chip) thereof to partially overlap the channel stopper region 11 (see FIGS. 19A and 19B) formed later, and the channel stopper region 11 need not necessarily be included in the opening closest to the end portion of the chip. On the other hand, it is necessary for the right end (end located inwardly in the chip) of the opening closest to the end portion of the chip to be located further inwardly of the right end of the channel stopper region 11 in the chip, and located inwardly of the right end (end located inwardly in the chip) of the P-type second well region 6C (see FIGS. 18A and 18B) formed later by a given distance (not particularly limited) in the chip. As for the openings other than the one closest to the end portion of the chip, the width of each of the other openings and the layout distance between the individual other openings may be the same as long as the other openings are located in the field portion R_{B}.

Next, the steps shown in FIGS. 4-9, 10A, and 10B according to the first example embodiment are performed. Here, when the step (step of forming the field insulating film 5) shown in FIG. 4 is performed, the impurity in the N-type impurity implanted layers 301 is thermally diffused to form the N-type depletion stop region 31 including the plurality of portions separated from each other. The impurity concentration of the N-type depletion stop region 31 is, e.g., 4×10¹⁷/cm³. That is, the impurity concentration of the N-type depletion stop region 31 is higher than the impurity concentration of the N-type epitaxial layer 2. Note that, in the third example embodiment, the one of the individual portions forming the depletion stop region 31 that is closest to the end portion of the chip is formed so as to extend from under the field insulating film 5 in the vicinity of the peripheral portion R_{C} to the epitaxial layer 2 (i.e., the second well region 6C (see FIGS. 18A and 18B)) in the peripheral portion R_{C}. The portions of the depletion stop region 31 other than the portion closest to the end portion of the chip are formed as a plurality of island portions spaced apart from each other in the field portion R_{B}, i.e., under the field insulating film 5 (see FIGS. 18A and 18B). Here, the width of each of the island portions and the layout distance between the individual island portions may be the same.

Next, the interlayer insulating film 13 is formed over the entire top surface of the semiconductor substrate 3, although the depiction thereof is omitted. Then, as shown in FIG. 18B associated with the cross-sectional structure along the line Q-Q′ of FIG. 1A, the respective portions of the interlayer insulating film 13 located in the areas where the source regions 12 (see FIG. 19B) are to be formed and in the area where the channel stopper region 11 (see FIGS. 19A and 19B) is to be formed are removed by a known etching technique to form openings. Thereafter, N-type impurity ions are implanted in the surface portions of the semiconductor substrate 3 through the openings, thereby forming the N-type impurity implanted layer 107 and the N-type impurity implanted layers 108 each having an impurity peak concentration at a position at a depth of about 0.03 μm from the top surface of the semiconductor substrate 3, and respectively serving as the channel stopper region 11 and the source regions 12. Examples of implantation conditions used at this time are such that an implanted impurity is arsenic, an implantation energy is 30 keV, and an amount of the implanted impurity (dose) is 3×10¹⁵/cm². At the same time as the step shown in FIG. 18B, as shown in FIG. 18A associated with the cross-sectional structure along the line P-P′ of FIG. 1A in which the P-type impurity implanted layers 106 serving as the body contact regions 10 (see FIG. 16A) have been formed in the step shown in FIG. 10A according to the first example embodiment, only the portion of the interlayer insulating film 13 located in the area where the channel stopper region 11 is to be formed is removed by a known etching technique to form the opening, and then N-type impurity ions are implanted into the surface portion of the semiconductor substrate 3 through the opening. That is, concerning the cross-sectional structure along the line P-P′ of FIG. 1A, the portions of the element portion R_{A} located in the areas where the body contact regions 10 are to be formed are covered with the interlayer insulating film 13 so that only the N-type impurity implanted layer 107 serving as the channel stopper region 11 is formed.

Next, the steps shown in FIGS. 12A and 12B according to the first example embodiment are performed. That is, as shown in FIG. 19A associated with the cross-sectional structure along the line P-P′ of FIG. 1A, the impurity in the P-type impurity implanted layers 106 serving as the body contact regions 10 and the impurity in the N-type impurity implanted layer 107 serving as the channel stopper region 11 are each diffused by a known thermal process using, e.g., RTA to form the P-type body contact regions 10 and the N-type channel stopper region 11. At the same time as the step shown in FIG. 19A, as shown in FIG. 19B associated with the cross-sectional structure along the line Q-Q′ of FIG. 1A, the impurity in the N-type impurity implanted layers 108 serving as the source regions 12 and the impurity in the N-type impurity implanted layer 107 serving as the channel stopper region 11 are each diffused by the foregoing thermal process to form the N-type source regions 12 and the N-type channel stopper region 11. That is, in the element portion R_{A}, the N-type source regions 12 are formed in the surface portions of the P-type first well region 6A so as to adjoin the buried gate electrodes 9A, and the P-type body contact regions 10 are formed in the surface portions of the P-type first well region 6A so as to adjoin each of the buried gate electrodes 9A and the source regions 12. Note that the impurity concentration of each of the body contact regions 10, the source regions 12, and the channel stopper region 11 is on the order of, e.g., 1×10²⁰/cm³. That is, the impurity concentration of the N-type channel stopper region 11 is higher than the impurity concentration of the N-type depletion stop region 31, and the impurity concentrations of the P-type body contact regions 10 are higher than the impurity concentration of the P-type first well region 6A. Note that, in the third example embodiment, the channel stopper region 11 is formed in the surface portion of the depletion stop region 31 located in the second well region 6C so as to be surrounded by the depletion stop region 31.

Next, as shown in FIG. 19A associated with the cross-sectional structure along the line P-P′ of FIG. 1A, the respective portions of the interlayer insulating film 13 located in the areas where the body contact regions 10 are to be formed and on the gate polysilicon layer 9B are simultaneously removed to form openings. Then, a conductive film made of, e.g., an aluminum film is deposited over the entire surface of the semiconductor substrate 3. Thereafter, by patterning the conductive film, the EQR electrode 14 electrically connected to the channel stopper region 11, the gate electrode 15 electrically connected to the gate polysilicon layer 9B, and the source electrode 16 electrically connected to the body contact regions 10 are formed individually. At the same time as the step shown in FIG. 19A, as shown in FIG. 19B associated with the cross-sectional structure along the line Q-Q′ of FIG. 1A, the portion of the interlayer insulating film 13 located on the gate polysilicon layer 9B is removed to form an opening. Then, by patterning the foregoing conductive film, the EQR electrode 14 electrically connected to the channel stopper region 11, the gate electrode 15 electrically connected to the gate polysilicon layer 9B, and the source electrode 16 electrically connected to the source regions 12 are formed individually. Thereafter, as shown in each of FIGS. 19A and 19B associated with the respective cross-sectional structures along the lines P-P′ and Q-Q′ of FIG. 1A, the drain electrode 17 made of, e.g., an aluminum film is formed on the back surface of the semiconductor substrate 3 (semiconductor substrate 1), whereby the semiconductor device according to the third example embodiment is completed. That is, in the semiconductor device (specifically the vertical element provided in the element portion R_{A}) according to the third example embodiment, when a predetermined voltage is applied to the source electrode 16 to apply a gate voltage to the buried gate electrode 9A buried in each of the trenches 7, a channel is formed along the wall surface of the trench 7 in the first well region 6A, and a drain current flows from the source regions 12 toward the area of the semiconductor substrate 1 serving as the drain region via the channel.

As described above, in the third example embodiment, the N-type channel stopper region 11 having a concentration of the order of, e.g., 1×10²⁰/cm³ is formed in the portion of the N-type epitaxial layer 2 having a concentration of the order of, e.g., 1×10¹⁶/cm³ which is located in the peripheral portion R_{C}, while the N-type depletion stop region 31 having a concentration (concentration of the order of, e.g., 1×10¹⁷/cm³) higher than that of the epitaxial layer 2 is formed in the epitaxial layer 2 so as to surround the channel stopper region 11 and extend further inwardly of the channel stopper region 11 in the chip (i.e., extend under the field insulating film 5). Here, the depletion stop region 31 includes the plurality of portions separated from each other, but the one of the individual portions forming the depletion stop region 31 that is closest to the end portion of the chip need not extend to the peripheral end of the chip as long as it partially overlaps the channel stopper region 11.

In such a structure according to the third example embodiment, even when ions that have entered the device from the outside thereof in a temperature cycle test are fixed in the field insulating film 5, and the top surface portion (i.e., the epitaxial layer 2) of the semiconductor substrate 3 in the field portion R_{B} is locally depleted, the formation of a depletion layer over the entire top surface of the epitaxial layer 2 from the element portion R_{A} to the peripheral portion R_{C} is suppressed. Therefore, in the insulated gate semiconductor device after the temperature cycle test, it is possible to suppress a leakage current from flowing between the element portion R_{A} and the peripheral portion R_{C}. Specifically, it is possible to completely inhibit the occurrence of a leakage current that has been conventionally monitored as a drain current larger than a normal drain current by about two orders of magnitude with a drain voltage lower than a breakdown voltage. In addition, even when the impurity concentration of the epitaxial layer 2 is reduced in response to a future request for a higher breakdown voltage placed on a vertical insulated gate semiconductor device, the depletion stop region 31 allows an increase in breakdown voltage without causing concern about the depletion of the top surface portion of the epitaxial layer 2 in the field portion R_{B}.

In the third example embodiment, the description has been given using the case where the N-channel trench MISFET is formed as the vertical element as an example. However, even when a P-channel trench MISFET is formed instead as the vertical element, the occurrence of a leakage current can be similarly inhibited. In this case, it is appropriate to use the same methods and conditions for forming the field insulating film, the gate insulating film, the gate electrode, and the like as used in the third example embodiment, and invert the conductivity types of impurity species to be implanted into various impurity regions (i.e., switch the conductivity type from the N-type to the P-type and from the P-type to the N-type). That is, by way of example, phosphorus is used for the formation of the well region, boron is used for the formation of the source regions and the channel stopper region, and phosphorus is used for the formation of the body contact regions. In the case of thus forming the P-channel trench MISFET as the vertical element also, even when the surface portion (i.e., the epitaxial layer) of the semiconductor substrate in the field portion R_{B} is locally depleted, the formation of a depletion layer over the entire top surface of the epitaxial layer from the element portion R_{A} to the peripheral portion R_{C} is suppressed. Therefore, in the insulated gate semiconductor device after the temperature cycle test, it is possible to suppress a leakage current from flowing between the element portion R_{A} and the peripheral portion R_{C}. In addition, even when the impurity concentration of the epitaxial layer is reduced in response to a future request for a higher breakdown voltage placed on a vertical insulated gate semiconductor device, the depletion stop region allows an increase in breakdown voltage without causing concern about the depletion of the top surface portion of the epitaxial layer in the field portion R_{B}.

It will be appreciated that various implantation conditions, thermal treatment conditions, impurity concentrations, and the like mentioned in the third example embodiment are only exemplary and that the present disclosure is not limited thereto.

In the third example embodiment, the source electrode 16 has been formed on each of the body contact regions 10 and the source regions 12. Instead, it is also possible that, while the source electrode is formed on the source regions 12, a body electrode separated from the source electrode may be formed on the body contact regions 10.

Alternatively, in the third example embodiment, the vertical element provided in the element portion R_{A} may also be, e.g., a vertical MISFET or a vertical IGBT.

What is claimed is:

1. A semiconductor device divided in an element portion in which a vertical element is disposed, a peripheral portion surrounding the element portion, and a field portion interposed between the element portion and the peripheral portion, the semiconductor device comprising:
a semiconductor substrate of a first conductivity type;
a semiconductor layer of the first conductivity type formed on a top surface of the semiconductor substrate, and having an impurity concentration lower than that of the semiconductor substrate;
a first well region of a second conductivity type formed in a portion of the semiconductor layer located in the element portion;
a second well region of the second conductivity type formed in a portion of the semiconductor layer located in the peripheral portion; and
a field insulating film formed on a portion of the semiconductor layer located in the field portion, wherein
a depletion stop region of the first conductivity type having an impurity concentration higher than that of the semiconductor layer is formed in a surface portion of the semiconductor layer located under at least a portion of the field insulating film adjacent to the peripheral portion.

2. The semiconductor device of claim 1, wherein the depletion stop region is formed so as to extend in the second well region.

3. The semiconductor device of claim 2, wherein
a channel stopper region of the first conductivity type having an impurity concentration higher than that of the depletion stop region is formed in a surface portion of the depletion stop region located in the second well region, and
a first electrode electrically connected to the channel stopper region is formed on the channel stopper region.

4. The semiconductor device of claim 2, wherein a first electrode electrically connected to the depletion stop region is formed on a portion of the depletion stop region located in the second well region.

5. The semiconductor device of claim 3, wherein the first electrode is an EQR electrode.

6. The semiconductor device of claim 1, wherein the depletion stop region includes a plurality of portions separated from each other.

7. The semiconductor device of claim 1, wherein
the first well region is formed to adjoin the field insulating film, and
a second electrode is formed on a portion of the first well region adjacent to the field insulating film with an insulating film interposed therebetween.

8. The semiconductor device of claim 7, wherein the second electrode is formed also on a portion of the field insulating film adjacent to the first well region.

9. The semiconductor device of claim 1, further comprising:
a trench formed so as to extend through the first well region; and
a buried gate electrode formed in the trench with a gate insulating film interposed between the buried gate electrode and the wall surface of the trench.

10. The semiconductor device of claim 9, further comprising:
a source region of the first conductivity type formed in a surface portion of the first well region to adjoin the buried gate electrode.

11. The semiconductor device of claim 10, further comprising:
a body contact region of the second conductivity type formed in a surface portion of the first well region to adjoin each of the buried gate electrode and the source region.

12. The semiconductor device of claim 11, further comprising:
a source electrode formed over the source region and the body contact region so as to electrically connect the source region and the body contact region; and
a drain electrode formed on the back surface of the semiconductor substrate.

13. The semiconductor device of claim 1, wherein the vertical element is a vertical MISFET or a vertical IGBT.

14. A method for fabricating a semiconductor device divided in an element portion in which a vertical element is disposed, a peripheral portion surrounding the element portion, and a field portion interposed between the element portion and the peripheral portion, the method comprising the steps of:
forming, on the top surface of a semiconductor substrate of a first conductivity type, a semiconductor layer of the first conductivity type having an impurity concentration lower than that of the semiconductor substrate;
forming a depletion stop region of the first conductivity type having an impurity concentration higher than that of the semiconductor layer in a surface portion of the semiconductor layer located in at least a portion of the field portion adjacent to the peripheral portion;
forming a field insulating film on a portion of the semiconductor layer located in the field portion so as to overlap at least a part of the depletion stop region; and
forming a first well region of a second conductivity type in a portion of the semiconductor layer located in the element portion, while forming a second well region of the second conductivity type in a portion of the semiconductor layer located in the peripheral portion.
